(19) United States
(12) Patent Application Publication
(10) Pub. No.: US 2025/0318202 A1
(43) Pub. Date: Oct. 9, 2025

(54) SEMICONDUCTOR DEVICE

(71) Applicant: Samsung Electronics Co., Ltd., Suwon-si (KR)

(72) Inventors: Seon Bae KIM, Suwon-si (KR); Heon Jong SHIN, Suwon-si (KR); Jae Hyun KANG, Suwon-si (KR); Doo Hyun LEE, Suwon-si (KR); Jin Wook LEE, Suwon-si (KR); Seung Hyun HWANG, Suwon-si (KR)

(21) Appl. No.: 18/925,203

(22) Filed: Oct. 24, 2024

(30) Foreign Application Priority Data
Apr. 8, 2024 (KR) 10-2024-0047287

(51) Int. Cl. H01L 29/786; H01L 29/06; H01L 29/417; H01L 29/423; H01L 29/66; H01L 29/775

(52) U.S. Cl. CPC H10D 30/6757; H10D 30/43; H10D 30/6219; H10D 30/6735; H10D 62/121; H10D 64/258; H10D 30/014; H10D 64/021

(57) ABSTRACT

A semiconductor device includes first and second insulating patterns extended in a first horizontal direction on a lower interlayer insulating layer, first and second plurality of nanosheets stacked on the first and second insulating patterns, a field insulating layer surrounding the first and second insulating patterns, a gate electrode on the first and second insulating patterns, first and second source/drain regions on one side of the gate electrode on the first and second insulating patterns, respectively, a first contact separating layer inside the upper interlayer insulating layer between the first and second source/drain regions, a second contact separating layer inside the upper interlayer insulating layer on the second source/drain region and contacting the first contact separating layer, and an upper source/drain contact electrically connected to the first source/drain region through the upper interlayer insulating layer in the vertical direction and contacting a sidewall of the first contact separating layer.

### CROSS-REFERENCE TO RELATED APPLICATION

This application claims priority under 35 U.S.C. § 119 from Korean Patent Application No. 10-2024-0047287, filed on Apr. 8, 2024, in the Korean Intellectual Property Office and all the benefits accruing therefrom under 35 U.S.C. § 119, the contents of which in its entirety are herein incorporated by reference.

### BACKGROUND

### Technical Field

The present disclosure relates to a semiconductor device, and more particularly, to a semiconductor device that includes a multi-bridge channel field effect transistor (MBCFET™).

### Description of the Related Art

As one of the scaling techniques for increasing a density of an integrated circuit device, a multi-gate transistor for forming a silicon body having a fin or nano-wire shape on a substrate and forming a gate on a surface of the silicon body has been suggested.

Since this multi-gate transistor uses a three-dimensional channel, it is easy to scale the multi-gate transistor. Also, even though a gate length of the multi-gate transistor is not increased, a current control capability may be improved. In addition, a short channel effect (SCE) in which a potential of a channel region is affected by a drain voltage may be suppressed effectively.

### SUMMARY

An object of the present disclosure is to provide a semiconductor device that makes sure of reliability of a source/drain region electrically connected to a lower source/drain contact by forming a contact separating layer on an upper surface of the source/drain region to which the lower source/drain contact is electrically connected.

According to some embodiments of the present disclosure, there is provided a semiconductor device, comprising a lower interlayer insulating layer, a first insulating pattern extended in a first horizontal direction on an upper surface of the lower interlayer insulating layer, a second insulating pattern extended in the first horizontal direction on the upper surface of the lower interlayer insulating layer, the second insulating pattern spaced apart from the first insulating pattern in a second horizontal direction different from the first horizontal direction, a first plurality of nanosheets stacked to be spaced apart from each other in a vertical direction on the first insulating pattern, a second plurality of nanosheets stacked to be spaced apart from each other in the vertical direction on the second insulating pattern, a field insulating layer surrounding sidewalls of the first and second insulating patterns on the upper surface of the lower interlayer insulating layer, a gate electrode extended in the second horizontal direction on the first and second insulating patterns, the gate electrode surrounding each of the first and second plurality of nanosheets, a first source/drain region disposed on one side of the gate electrode on the first insulating pattern, a second source/drain region disposed on the one side of the gate electrode on the second insulating pattern, an upper interlayer insulating layer covering the first and second source/drain regions on an upper surface of the field insulating layer, a first contact separating layer disposed inside the upper interlayer insulating layer between the first and second source/drain regions, the first contact separating layer including a material different from a material of the upper interlayer insulating layer, a second contact separating layer disposed inside the upper interlayer insulating layer on an upper surface of the second source/drain region, a lower surface of the second contact separating layer being at a level higher than a level of a lower surface of the first contact separating layer, the second contact separating layer including a material different from the material of the upper interlayer insulating layer, the second contact separating layer being in contact with the first contact separating layer, and an upper source/drain contact electrically connected to the first source/drain region by penetrating through the upper interlayer insulating layer in the vertical direction, the upper source/drain contact being in contact with a sidewall of the first contact separating layer in the first horizontal direction.

According to some embodiments of the present disclosure, there is provided a semiconductor device, comprising a lower interlayer insulating layer, a first insulating pattern extended in a first horizontal direction on an upper surface of the lower interlayer insulating layer, a second insulating pattern extended in the first horizontal direction on the upper surface of the lower interlayer insulating layer, the second insulating pattern spaced apart from the first insulating pattern in a second horizontal direction different from the first horizontal direction, a field insulating layer surrounding sidewalls of the first and second insulating patterns on the upper surface of the lower interlayer insulating layer, a gate electrode extended in the second horizontal direction on the first and second insulating patterns, a first source/drain region disposed on one side of the gate electrode on the first insulating pattern, a second source/drain region disposed on the one side of the gate electrode on the second insulating pattern, an upper interlayer insulating layer covering the first and second source/drain regions on an upper surface of the field insulating layer, an etching stop layer disposed between the upper surface of the field insulating layer and the upper interlayer insulating layer, the etching stop layer being in contact with a sidewall and an upper surface of the second source/drain region in the second horizontal direction, a first contact separating layer disposed inside the upper interlayer insulating layer between the first and second source/drain regions, the first contact separating layer including a material different from a material of the upper interlayer insulating layer, a second contact separating layer disposed inside the upper interlayer insulating layer on the upper surface of the second source/drain region, a lower surface of the second contact separating layer higher than a lower surface of the first contact separating layer, the second contact separating layer including a material different from the material of the upper interlayer insulating layer, the second contact separating layer being in contact with the first contact separating layer, and a lower source/drain contact electrically connected to the second source/drain region by penetrating through the lower interlayer insulating layer and the second insulating pattern in a vertical direction.

According to some embodiments of the present disclosure, there is provided a semiconductor device, comprising a lower interlayer insulating layer, a first insulating pattern extended in a first horizontal direction on an upper surface of the lower interlayer insulating layer, a second insulating pattern extended in the first horizontal direction on the upper surface of the lower interlayer insulating layer, the second insulating pattern being spaced apart from the first insulating pattern in a second horizontal direction different from the first horizontal direction, a first plurality of nanosheets stacked to be spaced apart from each other in a vertical direction on the first insulating pattern, a second plurality of nanosheets stacked to be spaced apart from each other in the vertical direction on the second insulating pattern, a field insulating layer surrounding sidewalls of the first and second insulating patterns on the upper surface of the lower interlayer insulating layer, a first gate electrode extended in the second horizontal direction on the first and second insulating patterns, the first gate electrode surrounding each of the first and second plurality of nanosheets, a second gate electrode extended in the second horizontal direction on the first and second insulating patterns, the second gate electrode being spaced apart from the first gate electrode in the first horizontal direction, a first source/drain region disposed between the first gate electrode and the second gate electrode on the first insulating pattern, a second source/drain region disposed between the first gate electrode and the second gate electrode on the second insulating pattern, an upper interlayer insulating layer covering the first and second source/drain regions on an upper surface of the field insulating layer, an etching stop layer disposed between the upper surface of the field insulating layer and the upper interlayer insulating layer, the etching stop layer being in contact with a sidewall and an upper surface of the second source/drain region in the second horizontal direction, a first contact separating layer disposed inside the upper interlayer insulating layer between the first and second source/drain regions, the first contact separating layer including a material different from a material of the upper interlayer insulating layer, a second contact separating layer disposed inside the upper interlayer insulating layer on the upper surface of the second source/drain region, a lower surface of the second contact separating layer being at a level higher than a level of a lower surface of the first contact separating layer, the second contact separating layer including the same material as the material of the first contact separating layer, the second contact separating layer being in contact with the first contact separating layer, an upper source/drain contact electrically connected to the first source/drain region by penetrating through the upper interlayer insulating layer in the vertical direction, the upper source/drain contact being in contact with a sidewall of the first contact separating layer in the first horizontal direction, and a lower source/drain contact electrically connected to the second source/drain region by penetrating through the lower interlayer insulating layer and the second insulating pattern in the vertical direction, wherein a lower surface of the upper source/drain contact is at a level higher than the level of the lower surface of the first contact separating layer, wherein the lower surface of the upper source/drain contact is at a level lower than a level of the lower surface of the second contact separating layer, wherein the lower surface of the first contact separating layer is in contact with the etching stop layer disposed on the upper surface of the field insulating layer, and wherein the lower surface of the second contact separating layer is in contact with the etching stop layer disposed on the upper surface of the second source/drain region.

The objects of the present disclosure are not limited to those mentioned above and additional objects of the present disclosure, which are not mentioned herein, will be clearly understood by those skilled in the art from the following description of the present disclosure.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a layout view illustrating a semiconductor device according to some example embodiments of the present disclosure;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIG. 5 is a cross-sectional view taken along line D-D′ of FIG. 1;

FIG. 6 is a cross-sectional view taken along line E-E′ of FIG. 1;

FIG. 7 is a cross-sectional view taken along line F-F′ of FIG. 1;

FIGS. 8 to 61 are views illustrating intermediate steps to describe a method for fabricating a semiconductor device according to some example embodiments of the present disclosure;

FIGS. 62 to 64 are cross-sectional views illustrating a semiconductor device according to some other example embodiments of the present disclosure;

FIGS. 65 and 66 are cross-sectional views illustrating a semiconductor device according to some other example embodiments of the present disclosure;

FIGS. 67 and 68 are cross-sectional views illustrating a semiconductor device according to some other example embodiments of the present disclosure; and

FIG. 69 is a cross-sectional view illustrating a semiconductor device according to some other example embodiments of the present disclosure.

### DETAILED DESCRIPTION OF THE DISCLOSURE

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

In the drawing related to a semiconductor device according to some embodiments, the semiconductor device will be described to include a transistor (multi-bridge channel field effect transistor (MBCFET™) including a nanosheet by way of example, but the present disclosure is not limited thereto. In some other embodiments, the semiconductor device may include a fin-type transistor (FinFET) including a channel region of a fin-type pattern shape, a tunneling transistor (tunneling FET) or a three-dimensional (3D) transistor. In addition, the semiconductor device according to some other embodiments may include a bipolar junction transistor, a laterally diffused metal oxide semiconductor (LDMOS) transistor and the like.

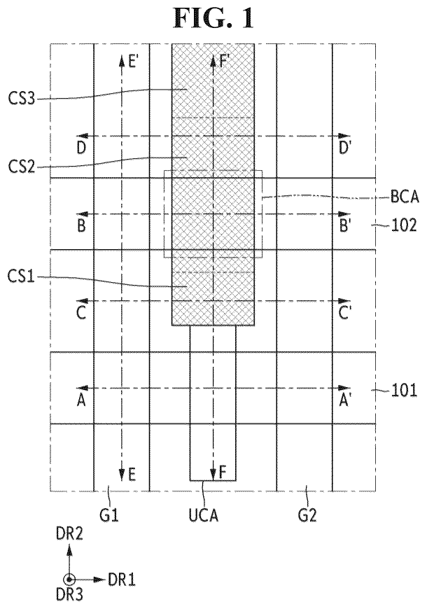

Hereinafter, the semiconductor device according to some example embodiments of the present disclosure will be described with reference to FIGS. 1 to 7.

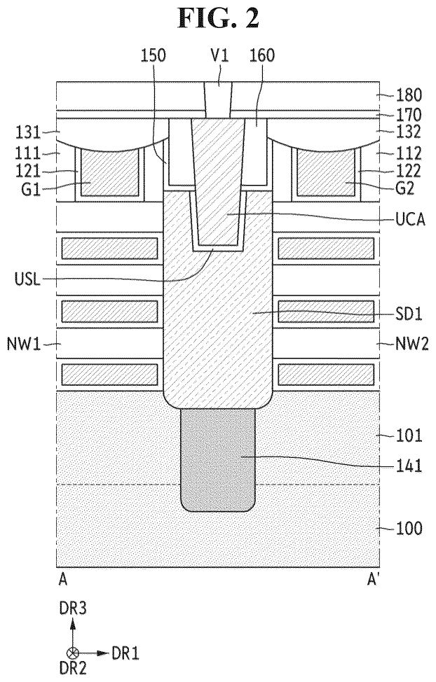

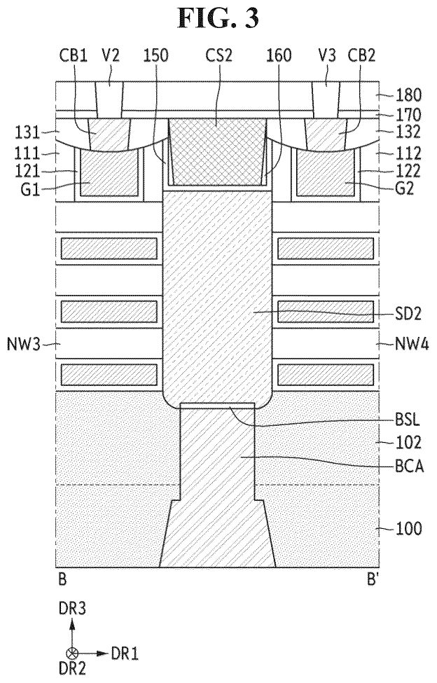

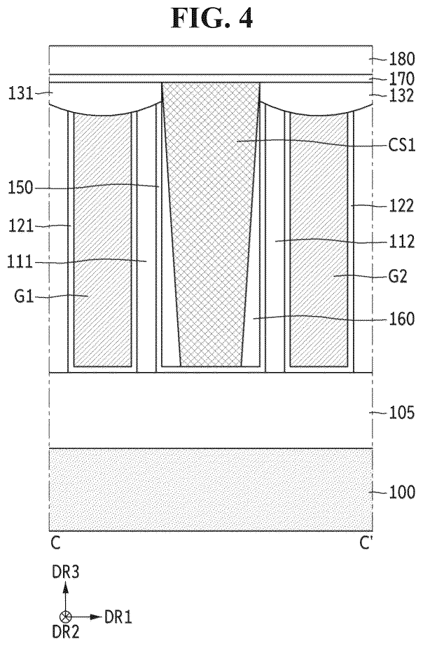

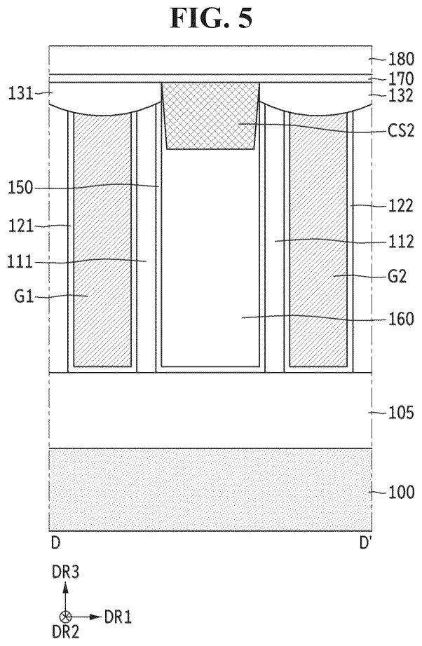

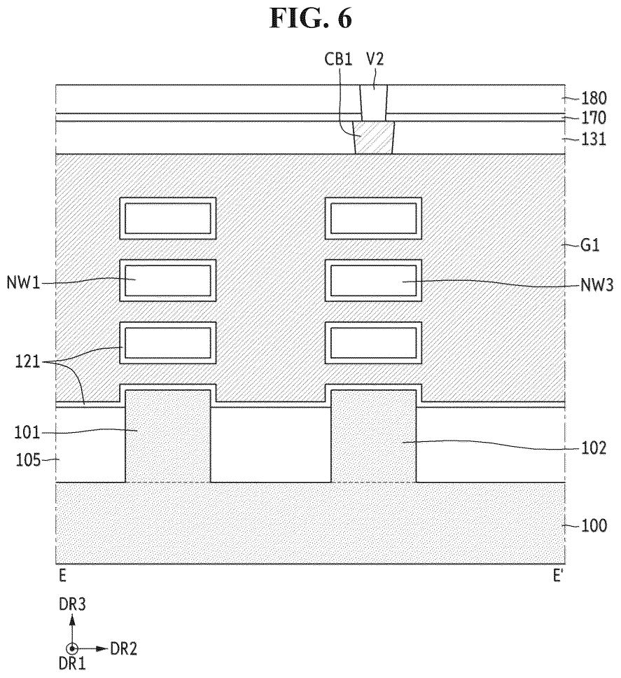

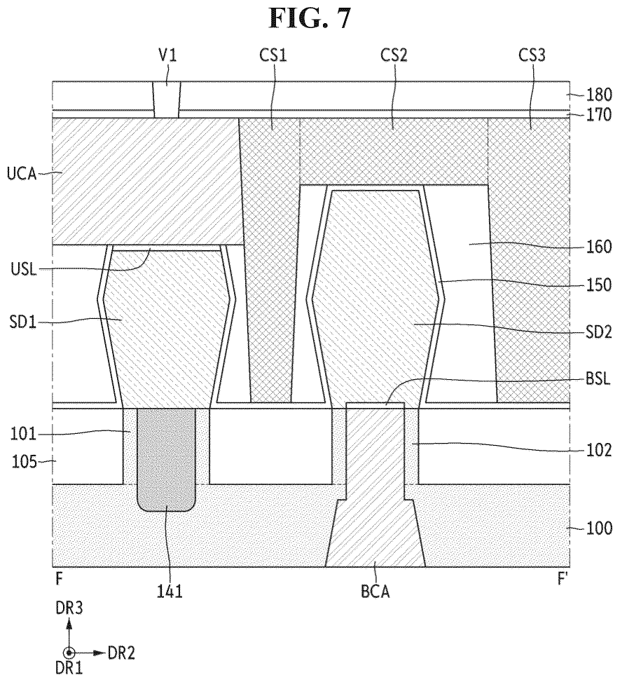

FIG. 1 is a layout view illustrating a semiconductor device according to some example embodiments of the present disclosure. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1. FIG. 5 is a cross-sectional view taken along line D-D′ of FIG. 1. FIG. 6 is a cross-sectional view taken along line E-E′ of FIG. 1. FIG. 7 is a cross-sectional view taken along line F-F′ of FIG. 1.

Referring to FIGS. 1 to 7, the semiconductor device according to some embodiments of the present disclosure includes a lower interlayer insulating layer 100, first and second insulating patterns 101 and 102, a field insulating layer 105, first to fourth plurality of nanosheets NW1 to NW4, first and second gate electrodes G1 and G2, first and second gate spacers 111 and 112, first and second gate insulating layers 121 and 122, first and second capping patterns 131 and 132, first and second source/drain regions SD1 and SD2, a first sacrificial pattern 141, a first etching stop layer 150, a first upper interlayer insulating layer 160, first to third contact separating layers CS1, CS2 and CS3, an upper source/drain contact UCA, a lower source/drain contact BCA, an upper silicide layer USL, a lower silicide layer BSL, first and second gate contacts CB1 and CB2, a second etching stop layer 170, a second upper interlayer insulating layer 180, and first to third vias V1, V2 and V3.

The lower interlayer insulating layer 100 may include at least one of, for example, silicon oxide, silicon nitride, silicon oxynitride or a low dielectric constant material. The low dielectric contact material may include Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SiLK, Amorphous Fluorinated Carbon, silica aerogels, silica xerogels, mesoporous silica or their combination, but the present disclosure is not limited thereto.

Hereinafter, each of a first horizontal direction DR1 and a second horizontal direction DR2 may be defined as a direction parallel with an upper surface of the lower interlayer insulating layer 100. The second horizontal direction DR2 may be defined as a direction different from the first horizontal direction DR1. The second horizontal direction DR2 may be defined as a direction perpendicular to the first horizontal direction DR1. A vertical direction DR3 may be defined as a direction perpendicular to each of the first horizontal direction DR1 and the second horizontal direction DR2. That is, the vertical direction DR3 may be defined as a direction perpendicular to the upper surface of the lower interlayer insulating layer 100.

The first insulating pattern 101 may extend lengthwise in the first horizontal direction DR1 on the upper surface of the lower interlayer insulating layer 100. The second insulating pattern 102 may extend lengthwise in the first horizontal direction DR1 on the upper surface of the lower interlayer insulating layer 100. The second insulating pattern 102 may be spaced apart from the first insulating pattern 101 in the second horizontal direction DR2. Each of the first and second insulating patterns 101 and 102 may protrude from the upper surface of the lower interlayer insulating layer 100 in the vertical direction DR3. Each of the first and second insulating patterns 101 and 102 may be formed of or include the same material as that of the lower interlayer insulating layer 100.

The field insulating layer 105 may be disposed on the upper surface of the lower interlayer insulating layer 100. The field insulating layer 105 may surround sidewalls of each of the first and second insulating patterns 101 and 102. For example, the field insulating layer 105 may contact an upper surface of the lower interlayer insulating layer 100 and side surfaces of the first and second insulating patterns 101 and 102. In example embodiments, an upper surface of each of the first and second insulating patterns 101 and 102 may be more protruded in the vertical direction DR3 than the upper surface of the field insulating layer 105. For example, upper surfaces of each of the first and second insulating patterns 101 and 102 may be at a higher vertical level than an upper surface of the field insulating layer 105, but the present disclosure is not limited thereto. In some other embodiments, the upper surface of each of the first and second insulating patterns 101 and 102 may be formed on the same plane as the upper surface of the field insulating layer 105. The field insulating layer 105 may be formed of or include, for example, an oxide layer, a nitride layer, an oxynitride layer or their combination layer.

The first plurality of nanosheets NW1 may be disposed on the first insulating pattern 101. The first plurality of nanosheets NW1 may be disposed on a portion where the first insulating pattern 101 and the first gate electrode G1 cross each other. The second plurality of nanosheets NW2 may be disposed on the first insulating pattern 101. The second plurality of nanosheets NW2 may be spaced apart from the first plurality of nanosheets NW1 in the first horizontal direction DR1. The second plurality of nanosheets NW2 may be disposed on a portion where the first insulating pattern 101 and the second gate electrode G2 cross each other. The third plurality of nanosheets NW3 may be disposed on the second insulating pattern 102. The third plurality of nanosheets NW3 may be spaced apart from the first plurality of nanosheets NW1 in the second horizontal direction DR2. The third plurality of nanosheets NW3 may be disposed on a portion where the second insulating pattern 102 and the first gate electrode G1 cross each other. The fourth plurality of nanosheets NW4 may be disposed on the second insulating pattern 102. The fourth plurality of nanosheets NW4 may be spaced apart from the second plurality of nanosheets NW2 in the second horizontal direction DR2. The fourth plurality of nanosheets NW4 may be disposed on a portion where the second insulating pattern 102 and the second gate electrode G2 cross each other.

Each of the first to fourth plurality of nanosheets NW1 to NW4 may include a plurality of nanosheets that are stacked to be spaced apart from each other in the vertical direction DR3. Although FIGS. 2 and 3 show that each of the first to fourth plurality of nanosheets NW1 to NW4 includes three nanosheets that are stacked to be spaced apart from one another in the vertical direction DR3, this is for convenience of description and the present disclosure is not limited thereto. In some other embodiments, each of the first to fourth plurality of nanosheets NW1 to NW4 may include four or more nanosheets stacked to be spaced apart from one another in the vertical direction DR3. For example, each of the first to fourth plurality of nanosheets NW1 to NW4 may be formed of or include silicon (Si), but the present disclosure is not limited thereto. In some other embodiments, each of the first to fourth plurality of nanosheets NW1 to NW4 may be formed of or include silicon germanium (SiGe).

The first gate electrode G1 may extend lengthwise in the second horizontal direction DR2 on the first insulating pattern 101, the second insulating pattern 102 and the field insulating layer 105. The first gate electrode G1 may surround each of the first plurality of nanosheets NW1 and the third plurality of nanosheets NW3. The second gate electrode G2 may extend lengthwise in the second horizontal direction DR2 on the first insulating pattern 101, the second insulating pattern 102 and the field insulating layer 105. The second gate electrode G2 may surround each of the second plurality of nanosheets NW2 and the fourth plurality of nanosheets NW4. The second gate electrode G2 may be spaced apart from the first gate electrode G1 in the first horizontal direction DR1.

Each of the first and second gate electrodes G1 and G2 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or their combination. Each of the first and second gate electrodes G1 and G2 may include a conductive metal oxide, a conductive metal oxynitride or the like, and may include an oxidized form of the above-described materials.

The first gate spacer 111 may extend lengthwise in the second horizontal direction DR2 along both sidewalls of the first gate electrode G1 on an upper surface of the uppermost nanosheet of the first plurality of nanosheets NW1, an upper surface of the uppermost nanosheet of the third plurality of nanosheets NW3 and the field insulating layer 105. The second gate spacer 112 may extend lengthwise in the second horizontal direction DR2 along both sidewalls of the second gate electrode G2 on an upper surface of the uppermost nanosheet of the second plurality of nanosheets NW2, an upper surface of the uppermost nanosheet of the fourth plurality of nanosheets NW4 and the field insulating layer 105. Each of the first and second gate spacers 111 and 112 may include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC) or their combination, but the present disclosure is not limited thereto.

The first source/drain region SD1 may be disposed between the first gate electrode G1 and the first second gate electrode G2 on the first insulating pattern 101. For example, the first source/drain region SD1 may be in contact with sidewalls of the first plurality of nanosheets NW1 in the first horizontal direction DR1 and sidewalls of the second plurality of nanosheets NW2 in the first horizontal direction DR1. The second source/drain region SD2 may be disposed between the first gate electrode G1 and the second gate electrode G2 on the second insulating pattern 102. For example, the second source/drain region SD2 may be in contact with sidewalls of the third plurality of nanosheets NW3 in the first horizontal direction DR1 and sidewalls of the fourth plurality of nanosheets NW4 in the first horizontal direction DR1. For example, a lower surface of the first source/drain region SD1 may be in contact with the upper surface of the first insulating pattern 101. Also, a lower surface of the second source/drain region SD2 may be in contact with the upper surface of the second insulating pattern 102. For example, an upper surface of each of the first and second source/drain regions SD1 and SD2 may be formed to be higher than the upper surfaces of the uppermost nanosheets of the first to fourth plurality of nanosheets NW1 to NW4.

The first gate insulating layer 121 may be disposed between the first gate electrode G1 and the field insulating layer 105. The first gate insulating layer 121 may be disposed between the first gate electrode G1 and the first gate spacer 111. The first gate insulating layer 121 may be disposed between the first gate electrode G1 and the first plurality of nanosheets NW1. The first gate insulating layer 121 may be disposed between the first gate electrode G1 and the third plurality of nanosheets NW3. The first gate insulating layer 121 may be disposed between the first gate electrode G1 and the first source/drain region SD1. The first gate insulating layer 121 may be disposed between the first gate electrode G1 and the second source/drain region SD2. The first gate insulating layer 121 may contact the first gate electrode G1, the field insulating layer 105, the first gate spacer 111, and the first and third plurality of nanosheets NW1 and NW3.

The second gate insulating layer 122 may be disposed between the second gate electrode G2 and the field insulating layer 105. The second gate insulating layer 122 may be disposed between the second gate electrode G2 and the second gate spacer 112. The second gate insulating layer 122 may be disposed between the second gate electrode G2 and the second plurality of nanosheets NW2. The second gate insulating layer 122 may be disposed between the second gate electrode G2 and the fourth plurality of nanosheets NW4. The second gate insulating layer 122 may be disposed between the second gate electrode G2 and the first source/drain region SD1. The second gate insulating layer 122 may be disposed between the second gate electrode G2 and the second source/drain region SD2. The second gate insulating layer 122 may contact the second gate electrode G2, the field insulating layer 105, the second gate spacer 112, and the second and fourth plurality of nanosheets NW2 and NW4.

For example, each of the first and second gate insulating layers 121 and 122 may be in contact with the first insulating pattern 101. Also, each of the first and second gate insulating layers 121 and 122 may be in contact with the second insulating pattern 102. For example, each of the first and second gate insulating layers 121 and 122 may be in contact with the first source/drain region SD1. Also, each of the first and second gate insulating layers 121 and 122 may be in contact with the second source/drain region SD2, but the present disclosure is not limited thereto. In some other embodiments, an inner spacer may be disposed between each of the first and second gate insulating layers 121 and 122 and the first source/drain region SD1. Also, an inner spacer may be disposed between each of the first and second gate insulating layers 121 and 122 and the second source/drain region SD2. The inner spacer may include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC) or their combination.

Each of the first and second gate insulating layers 121 and 122 may include at least one of silicon oxide, silicon oxynitride, silicon nitride, or a high dielectric constant material having a dielectric constant greater than that of the silicon oxide. The high dielectric constant material may include one or more of, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some other embodiments may include a negative capacitance (NC) FET based on a negative capacitor. For example, each of the first and second gate insulating layers 121 and 122 may include a ferroelectric material layer having ferroelectric characteristics and a paraelectric material layer having paraelectric characteristics.

The ferroelectric material layer may have a negative capacitance, and the paraelectric material layer may have a positive capacitance. For example, when two or more capacitors are connected in series, and the capacitance of each capacitor has a positive value, the total capacitance is more reduced than the capacitance of each individual capacitor. On the other hand, when at least one of capacitances of two or more capacitors connected in series has a negative value, the total capacitance may have a positive value and may be greater than an absolute value of each individual capacitance.

When a ferroelectric material layer having a negative capacitance and a paraelectric material layer having a positive capacitance are connected in series, the total capacitance value of the ferroelectric material layer and the paraelectric material layer, which are connected in series, may be increased. Based on the total capacitance value that is increased, a transistor having a ferroelectric material layer may have a subthreshold swing (SS) less than 60 mV/decade at a room temperature.

The ferroelectric material layer may have ferroelectric characteristics. The ferroelectric material layer may include at least one of, for example, hafnium oxide, hafnium zirconium oxide, barium strontium titanium oxide, barium titanium oxide, or lead zirconium titanium oxide. In this case, for example, the hafnium zirconium oxide may be a material doped with zirconium (Zr) in hafnium oxide. For another example, the hafnium zirconium oxide may be a compound of hafnium (Hf), zirconium (Zr) and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A type of the dopant included in the ferroelectric material layer may be varied depending on the ferroelectric material of the ferroelectric material layer.

When the ferroelectric material layer includes hafnium oxide, the dopant included in the ferroelectric material layer may include at least one of gadolinium (Gd), silicon (Si), zirconium (Zr), aluminum (Al), or yttrium (Y).

When the dopant is aluminum (Al), the ferroelectric material layer may include aluminum of 3 at % to 8 at % (atomic%). In this case, a ratio of the dopant may be a ratio of aluminum to a sum of hafnium and aluminum.

When the dopant is silicon (Si), the ferroelectric material layer may include silicon of 2 at % to 10 at %. When the dopant is yttrium (Y), the ferroelectric material layer may include yttrium of 2 at % to 10 at %. When the dopant is gadolinium (Gd), the ferroelectric material layer may include gadolinium of 1 at % to 7 at %. When the dopant is zirconium (Zr), the ferroelectric material layer may include zirconium of 50 at % to 80 at %.

The paraelectric material layer may have paraelectric characteristics. The paraelectric material layer may include at least one of, for example, silicon oxide or metal oxide having a high dielectric constant. The metal oxide included in the paraelectric material layer may include, but is not limited to, at least one of hafnium oxide, zirconium oxide, or aluminum oxide.

The ferroelectric material layer and the paraelectric material layer may be formed of or include the same material. Although the ferroelectric material layer has ferroelectric characteristics, the paraelectric material layer may not have ferroelectric characteristics. For example, when the ferroelectric material layer and the paraelectric material layer include hafnium oxide, a crystal structure of hafnium oxide included in the ferroelectric material layer is different from that of hafnium oxide included in the paraelectric material layer.

The ferroelectric material layer may have a thickness having ferroelectric characteristics. The thickness of the ferroelectric material layer may be, for example, 0.5 nm to 10 nm, but is not limited thereto. Since a threshold thickness indicating ferroelectric characteristics may be varied depending on each ferroelectric material, the thickness of the ferroelectric material layer may be varied depending on the ferroelectric material.

For example, each of the first and second gate insulating layers 121 and 122 may include one ferroelectric material layer. For another example, each of the first and second gate insulating layers 121 and 122 may include a plurality of ferroelectric material layers spaced apart from each other. The first and second gate insulating layers 121 and 122 may have a stacked layer structure in which a plurality of ferroelectric material layers and a plurality of paraelectric material layers are alternately stacked.

The first etching stop layer 150 may be disposed on sidewalls of each of the first and second gate spacers 111 and 112 in the first horizontal direction DR1. The first etching stop layer 150 may be disposed on the upper surface of the field insulating layer 105. For example, the first etching stop layer 150 may contact the sidewalls of each of the first and second gate spacers 111 and 112 and the upper surface of the field insulating layer 105. The first etching stop layer 150 may be disposed on the upper surface of each of the first and second source/drain regions SD1 and SD2. The first etching stop layer 150 may be disposed on sidewalls of each of the first and second source/drain regions SD1 and SD2 in the second horizontal direction DR2. The first etching stop layer 150 may be in contact with the sidewalls and the upper surface of each of the first and second source/drain regions SD1 and SD2 in the second horizontal direction DR2, respectively. For example, the first etching stop layer 150 may be formed to be conformal. The first etching stop layer 150 may include at least one of, for example, aluminum oxide, aluminum nitride, hafnium oxide, zirconium oxide, silicon oxide, silicon nitride, silicon oxynitride or a low dielectric constant material.

The first capping pattern 131 may extend lengthwise in the second horizontal direction DR2 on each of the first gate spacer 111, the first gate insulating layer 121 and the first gate electrode G1. For example, the first capping pattern 131 may contact upper surfaces of each of the first gate spacer 111, the first gate insulating layer 121 and the first gate electrode G1. The second capping pattern 132 may extend in the second horizontal direction DR2 on each of the second gate spacer 112, the second gate insulating layer 122 and the second gate electrode G2. For example, the second capping pattern 132 may contact upper surfaces of each of the second gate spacer 112, the second gate insulating layer 122 and the second gate electrode G2. For example, a lower surface of each of the first and second capping patterns 131 and 132 may be in contact with the first etching stop layer 150, but the present disclosure is not limited thereto. In some other embodiments, a sidewall of each of the first and second capping patterns 131 and 132 may be in contact with the first etching stop layer 150. Each of the first and second capping patterns 131 and 132 may include at least one of, for example, silicon nitride (SiN), silicon oxynitride (SiON), silicon oxide (SiO₂), silicon carbonitride (SiCN), silicon oxycarbonitride (SiOCN) or their combination, but the present disclosure is not limited thereto.

The first upper interlayer insulating layer 160 may be disposed on the first etching stop layer 150. For example, the first upper interlayer insulating layer 160 may contact the first etching stop layer 150. The first upper interlayer insulating layer 160 may be disposed on the sidewall of each of the first and second capping patterns 131 and 132. For example, the first upper interlayer insulating layer 160 may contact the sidewall of each of the first and second capping patterns 131 and 132. The first upper interlayer insulating layer 160 may cover the first and second source/drain regions SD1 and SD2 on the field insulating layer 105, respectively. For example, an upper surface of the first upper interlayer insulating layer 160 may be formed on the same plane as an upper surface of each of the first and second capping patterns 131 and 132. The first upper interlayer insulating layer 160 may include at least one of, for example, silicon oxide, silicon nitride, silicon oxynitride or a low dielectric constant material.

The first contact separating layer CS1 may be disposed between the first gate electrode G1 and the second gate electrode G2 on the field insulating layer 105. Also, the first contact separating layer CS1 may be disposed between the first source/drain region SD1 and the second source/drain region SD2 on the field insulating layer 105. For example, the first contact separating layer CS1 may be spaced apart from each of the first and second source/drain regions SD1 and SD2 in the second horizontal direction DR2. The first contact separating layer CS1 may be disposed inside the first upper interlayer insulating layer 160. The first contact separating layer CS1 may pass through the first upper interlayer insulating layer 160 in the vertical direction DR3. The first upper interlayer insulating layer 160 may contact sidewalls of the first contact separating layer CS1. For example, a lower surface of the first contact separating layer CS1 may be in contact with the first etching stop layer 150 disposed on the upper surface of the field insulating layer 105.

The third contact separating layer CS3 may be disposed between the first gate electrode G1 and the second gate electrode G2 on the field insulating layer 105. For example, the third contact separating layer CS3 may be spaced apart from the second source/drain region SD2 in the second horizontal direction DR2. The third contact separating layer CS3 may be disposed inside the first upper interlayer insulating layer 160. The third contact separating layer CS3 may pass through the first upper interlayer insulating layer 160 in the vertical direction DR3. The first upper interlayer insulating layer 160 may contact sidewalls of the third contact separating layer CS3. For example, a lower surface of the third contact separating layer CS3 may be in contact with the first etching stop layer 150 disposed on the upper surface of the field insulating layer 105. In example embodiments, the lower surface of the third contact separating layer CS3 may be at the same vertical level as the lower surface of the first contact separating layer CS1.

The second contact separating layer CS2 may be disposed between the first gate electrode G1 and the second gate electrode G2 on the second insulating pattern 102 and the field insulating layer 105. The second contact separating layer CS2 may be disposed between the first contact separating layer CS1 and the third contact separating layer CS3 on the second insulating pattern 102 and the field insulating layer 105. For example, both sidewalls of the second contact separating layer CS2 in the second horizontal direction DR2 may be in contact with each of the first contact separating layer CS1 and the third contact separating layer CS3. The second contact separating layer CS2 may be disposed on the upper surface of the second source/drain region SD2. That is, the second contact separating layer CS2 may overlap the second source/drain region SD2 in the vertical direction DR3. For example, a lower surface of the second contact separating layer CS2 may be in contact with the first etching stop layer 150 disposed on the upper surface of the second source/drain region SD2. For example, the lower surface of the second contact separating layer CS2 may be formed to be higher than the lower surface of the first contact separating layer CS1 and the lower surface of the third contact separating layer CS3, respectively. For example, the lower surface of the second contact separating layer CS2 may be formed to be higher than the upper surface of the second source/drain region SD2. The lower surface of the second contact separating layer CS2 may contact an upper surface of the first upper interlayer insulating layer 160.

For example, both sidewalls of each of the first to third contact separating layers CS1, CS2 and CS3 in the first horizontal direction DR1 may be in contact with the first capping pattern 131 and the second capping pattern 132, but the present disclosure is not limited thereto. For example, an upper surface of each of the first to third contact separating layers CS1, CS2 and CS3 may be formed on the same plane as the upper surface of each of the first and second capping patterns 131 and 132. For example, the upper surface of each of the first to third contact separating layers CS1, CS2 and CS3 may be formed on the same plane. For example, the upper surface of each of the first to third contact separating layers CS1, CS2 and CS3 may be formed on the same plane as the upper surface of the first upper interlayer insulating layer 160.

Each of the first to third contact separating layers CS1, CS2 and CS3 may include an insulating material. For example, each of the first to third contact separating layers CS1, CS2 and CS3 may be formed of or include a material different from that of the first upper interlayer insulating layer 160. The first to third contact separating layers CS1, CS2 and CS3 may be formed of or include the same material. For example, each of the first to third contact separating layers CS1, CS2 and CS3 may be formed of or include silicon nitride (SiN), silicon oxynitride (SiON), silicon carbonitride (SiCN), silicon oxycarbide (SiOC) or silicon oxycarbonitride (SiOCN), but the present disclosure is not limited thereto.

The upper source/drain contact UCA may be disposed between the first gate electrode G1 and the second gate electrode G2. The upper source/drain contact UCA may be disposed above the first source/drain region SD1. The upper source/drain contact UCA may be extended into the first source/drain region SD1 by penetrating through the first upper interlayer insulating layer 160 and the first etching stop layer 150 in the vertical direction DR3. The upper source/drain contact UCA may be electrically connected to the first source/drain region SD1.

For example, a sidewall of the upper source/drain contact UCA in the second horizontal direction DR2 may be in contact with a sidewall of the first contact separating layer CS1. For example, an upper surface of the upper source/drain contact UCA may be formed on the same plane as the upper surface of each of the first to third contact separating layers CS1, CS2 and CS3. For example, the upper surface of the upper source/drain contact UCA may be formed on the same plane as the upper surface of the first upper interlayer insulating layer 160. For example, a lower surface of the upper source/drain contact UCA may be formed to be higher than each of the lower surface of the first contact separating layer CS1 and the lower surface of the third contact separating layer CS3. For example, the lower surface of the upper source/drain contact UCA may be formed to be lower than the lower surface of the second contact separating layer CS2. Although FIGS. 2 and 7 show that the upper source/drain contact UCA is formed as a single layer, the present disclosure is not limited thereto. In some other embodiments, the upper source/drain contact UCA may be formed of a multi-layer. The upper source/drain contact UCA may include a conductive material.

The upper silicide layer USL may be disposed between the upper source/drain contact UCA and the first source/drain region SD1. The upper silicide layer USL may be disposed along a boundary surface between the upper source/drain contact UCA and the first source/drain region SD1. The upper silicide layer USL may contact the upper source/drain contact UCA and the first source/drain region SD1. The upper silicide layer USL may include, for example, a metal silicide material.

The first gate contact CB1 may be disposed above the first gate electrode G1. The first gate contact CB1 may be connected to the first gate electrode G1 by penetrating through the first capping pattern 131 in the vertical direction DR3. For example, the first capping pattern 131 may contact sidewalls of the first gate contact CB1. The second gate contact CB2 may be disposed above the second gate electrode G2. The second gate contact CB2 may be connected to the second gate electrode G2 by penetrating through the second capping pattern 132 in the vertical direction DR3. For example, the second capping pattern 132 may contact sidewalls of the second gate contact CB2. Although FIG. 3 shows that each of the first and second gate contacts CB1 and CB2 is formed as a single layer, the present disclosure is not limited thereto. In some other embodiments, each of the first and second gate contacts CB1 and CB2 may be formed as a multi-layer. For example, an upper surface of each of the first and second gate contacts CB1 and CB2 may be formed on the same plane as each of the upper surface of the upper source/drain contact UCA and the upper surface of the first upper interlayer insulating layer 160, but the present disclosure is not limited thereto. Each of the first and second gate contacts CB1 and CB2 may include a conductive material.

The lower source/drain contact BCA may be disposed between the first gate electrode G1 and the second gate electrode G2. The lower source/drain contact BCA may be disposed below the second source/drain region SD2. The lower source/drain contact BCA may be connected to the second source/drain region SD2 by penetrating through the lower interlayer insulating layer 100 and the second insulating pattern 102 in the vertical direction DR3. For example, sidewalls of the lower source/drain contact BCA may be surrounded by the lower interlayer insulating layer 100 and the second insulating pattern 102. For example, the sidewalls of the lower source/drain contact BCA may be in contact with each of the lower interlayer insulating layer 100 and the second insulating pattern 102.

For example, the lower source/drain contact BCA may be disposed below the second contact separating layer CS2. That is, the lower source/drain contact BCA may overlap the second contact separating layer CS2 in the vertical direction DR3. For example, the upper surface of the lower source/drain contact BCA may be formed on the same plane as the upper surface of the second insulating pattern 102, but the present disclosure is not limited thereto. Although FIGS. 3 and 7 show that the lower source/drain contact BCA is formed as a single layer, the present disclosure is not limited thereto. In some other embodiments, the lower source/drain contact BCA may be formed as a multi-layer. The lower source/drain contact BCA may include a conductive material.

The lower silicide layer BSL may be disposed between the lower source/drain contact BCA and the second source/drain region SD2. The lower silicide layer BSL may be disposed along a boundary surface between the lower source/drain contact BCA and the second source/drain region SD2. The lower silicide layer BSL may contact the lower source/drain contact BCA and the second source/drain region SD2. The lower silicide layer BSL may include, for example, a metal silicide material.

The first sacrificial pattern 141 may be disposed below the first source/drain region SD1. An upper surface of the first sacrificial pattern 141 may be in contact with the lower surface of the first source/drain region SD1. For example, sidewalls of the first sacrificial pattern 141 may be surrounded by the first insulating pattern 101. For example, both sidewalls of the first sacrificial pattern 141 in the first horizontal direction DR1 may be in contact with the first insulating pattern 101 and the lower interlayer insulating layer 100, respectively. For example, a lower surface of the first sacrificial pattern 141 may be in contact with the lower interlayer insulating layer 100, but the present disclosure is not limited thereto. In some other embodiments, the lower surface of the first sacrificial pattern 141 may be in contact with the first insulating pattern 101.

For example, the upper surface of the first sacrificial pattern 141 may be formed to be lower than the upper surface of the first insulating pattern 101. For example, a width of the first sacrificial pattern 141 in the first horizontal direction DR1 may be smaller than that of the first source/drain region SD1 in the first horizontal direction DR1. Also, a width of the first sacrificial pattern 141 in the second horizontal direction DR2 may be smaller than that of the first source/drain region SD1 in the second horizontal direction DR2. For example, the first sacrificial pattern 141 may be formed of or include silicon germanium (SiGe).

The second etching stop layer 170 may be disposed on the upper surface of each of the upper source/drain contact UCA, the first and second capping patterns 131 and 132, the first upper interlayer insulating layer 160, and the first to third contact separating layers CS1, CS2 and CS3. The second etching stop layer 170 may contact the upper surface of each of the upper source/drain contact UCA, the first and second capping patterns 131 and 132, the first upper interlayer insulating layer 160, and the first to third contact separating layers CS1, CS2 and CS3. Although FIGS. 2 to 7 show that the second etching stop layer 170 is formed as a single layer, the present disclosure is not limited thereto. In some other embodiments, the second etching stop layer 170 may be formed as a multi-layer. The second etching stop layer 170 may include at least one of, for example, aluminum oxide, aluminum nitride, hafnium oxide, zirconium oxide, silicon oxide, silicon nitride, silicon oxynitride or a low dielectric constant material. The second upper interlayer insulating layer 180 may be disposed on the second etching stop layer 170. The second upper interlayer insulating layer 180 may contact an upper surface of the second etching stop layer 170. The second upper interlayer insulating layer 180 may include at least one of, for example, silicon oxide, silicon nitride, silicon oxynitride or a low dielectric constant material.

The first via V1 may be connected to the upper source/drain contact UCA by penetrating through the second upper interlayer insulating layer 180 and the second etching stop layer 170 in the vertical direction DR3. The second upper interlayer insulating layer 180 and the second etching stop layer 170 may contact sidewalls of the first via V1. The second via V2 may be connected to the first gate contact CB1 by penetrating through the second upper interlayer insulating layer 180 and the second etching stop layer 170 in the vertical direction DR3. The second upper interlayer insulating layer 180 and the second etching stop layer 170 may contact sidewalls of the second via V2. The third via V3 may be connected to the second gate contact CB2 by penetrating through the second upper interlayer insulating layer 180 and the second etching stop layer 170 in the vertical direction DR3. The second upper interlayer insulating layer 180 and the second etching stop layer 170 may contact sidewalls of the third via V3. Although FIGS. 2 and 3 show that each of the first to third vias V1, V2 and V3 is formed as a single layer, but the present disclosure is not limited thereto. In some other embodiments, each of the first to third vias V1, V2 and V3 may be formed as a multi-layer. Each of the first to third vias V1, V2 and V3 may include a conductive material.

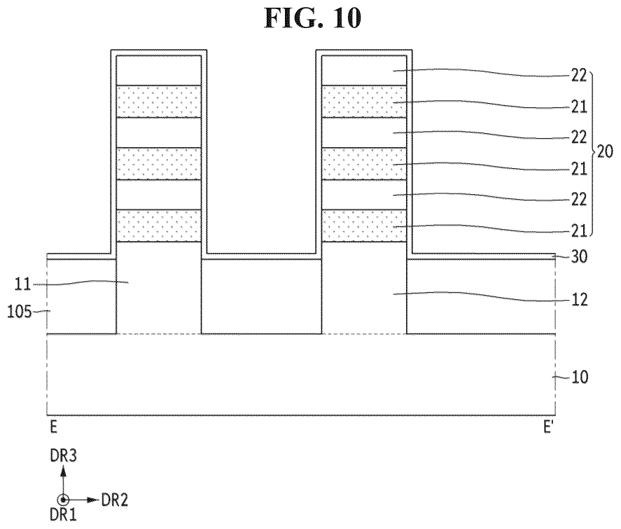

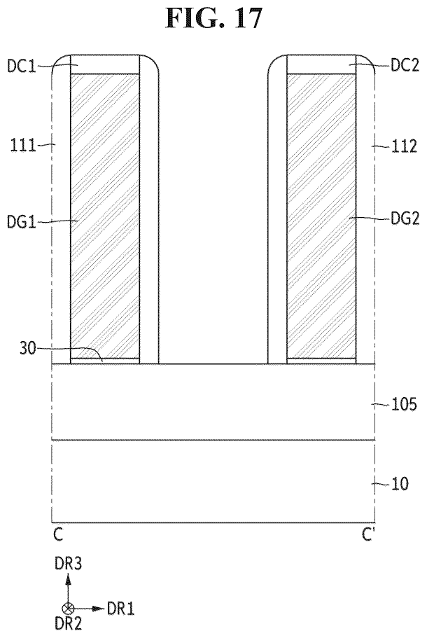

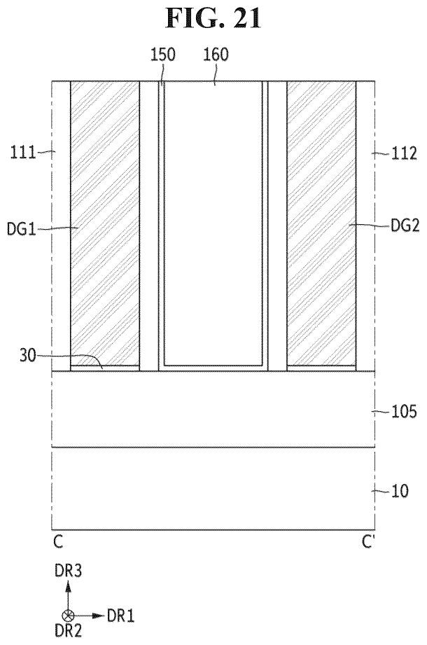

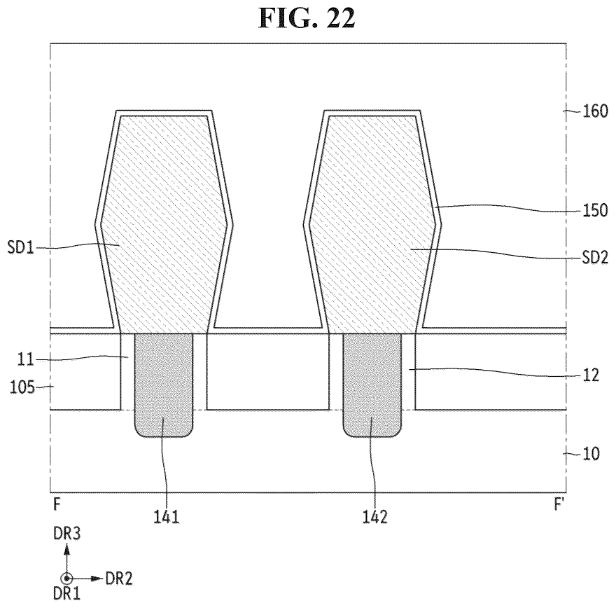

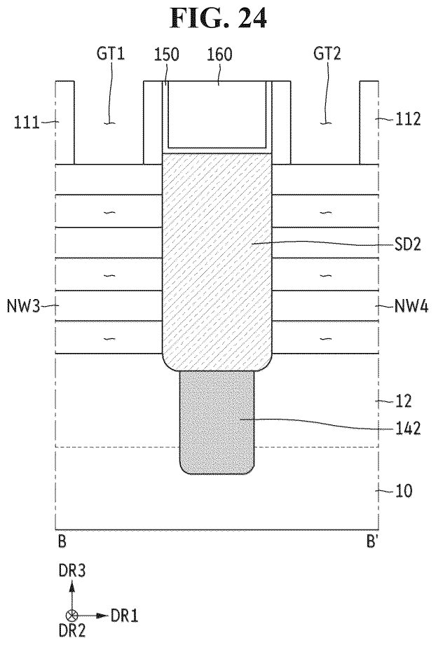

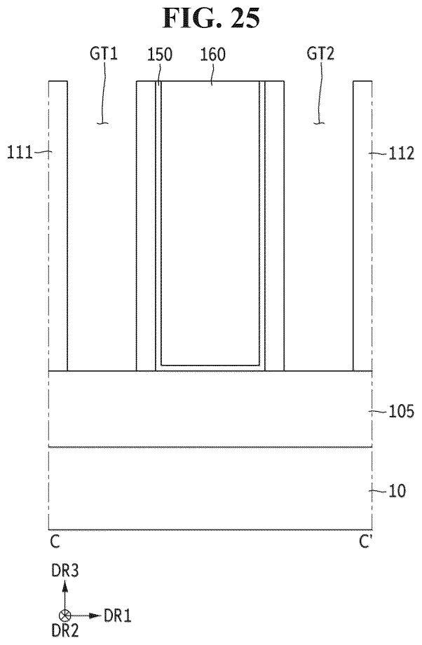

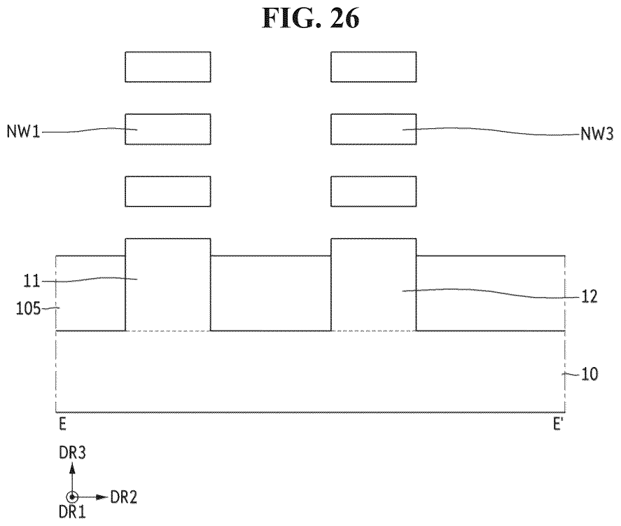

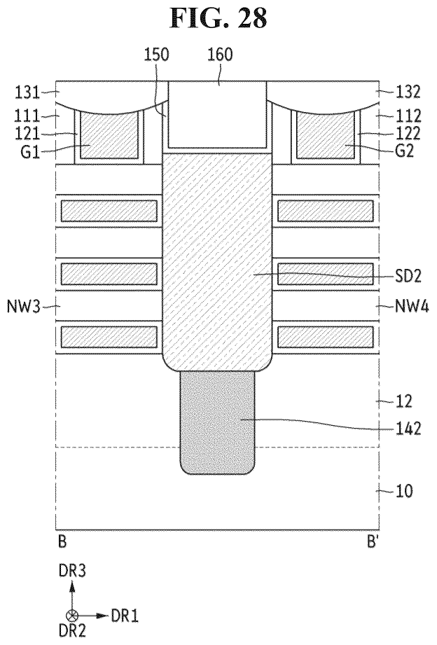

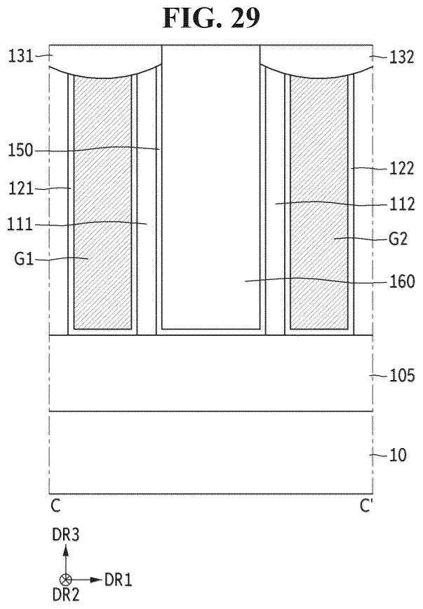

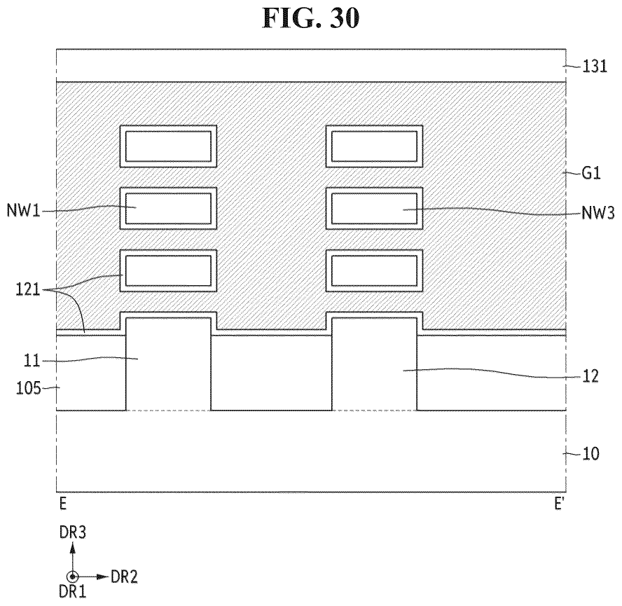

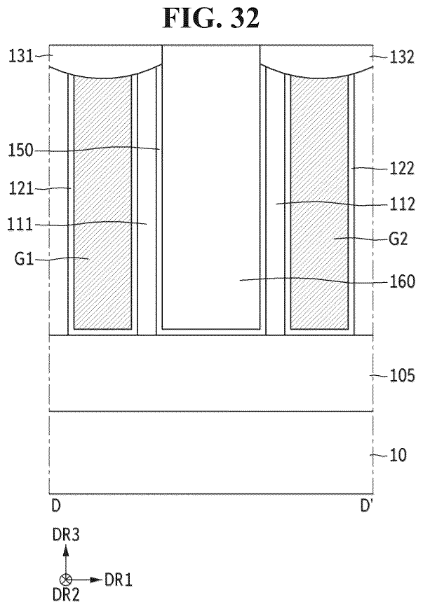

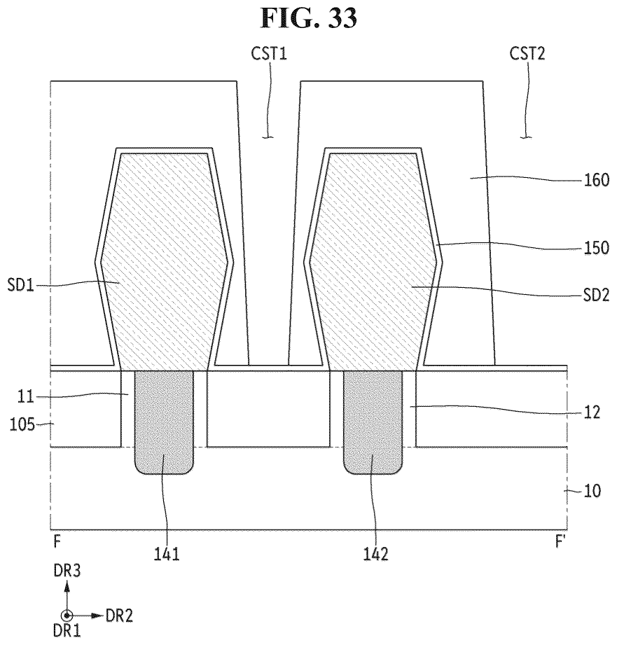

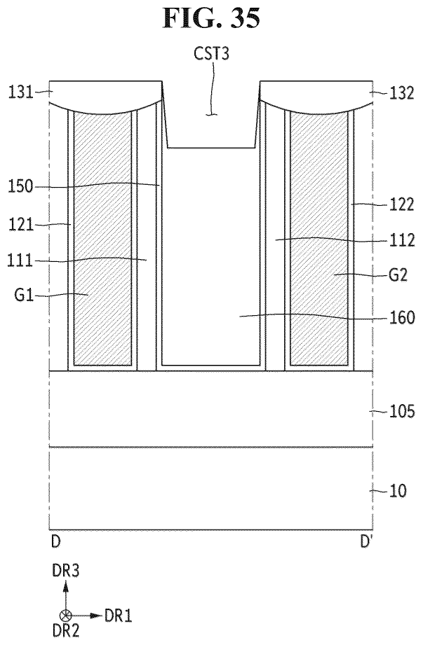

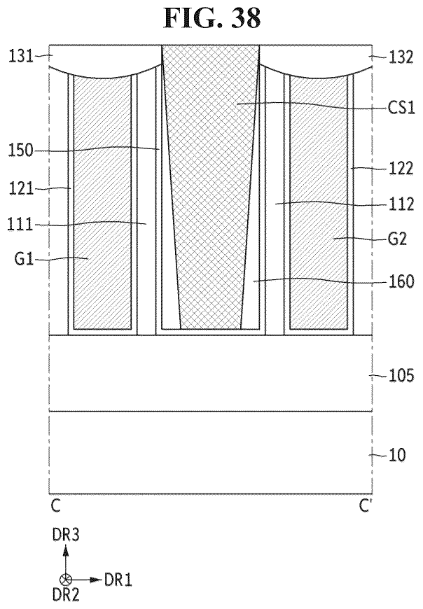

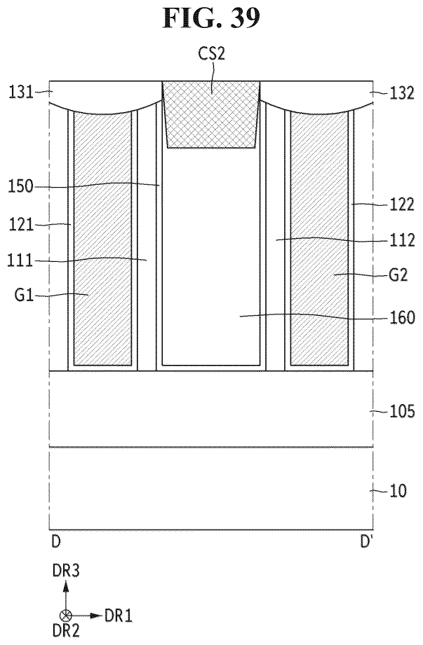

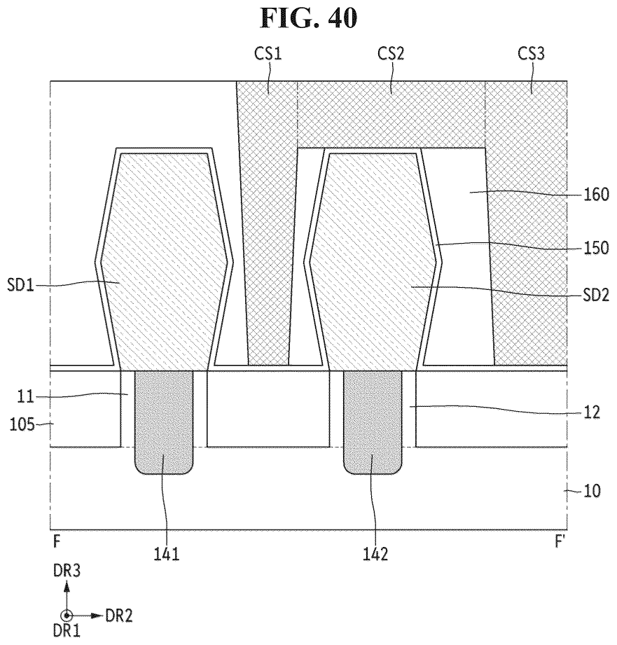

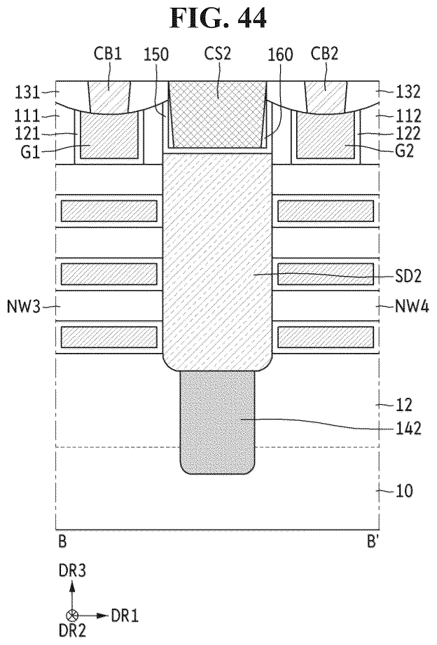

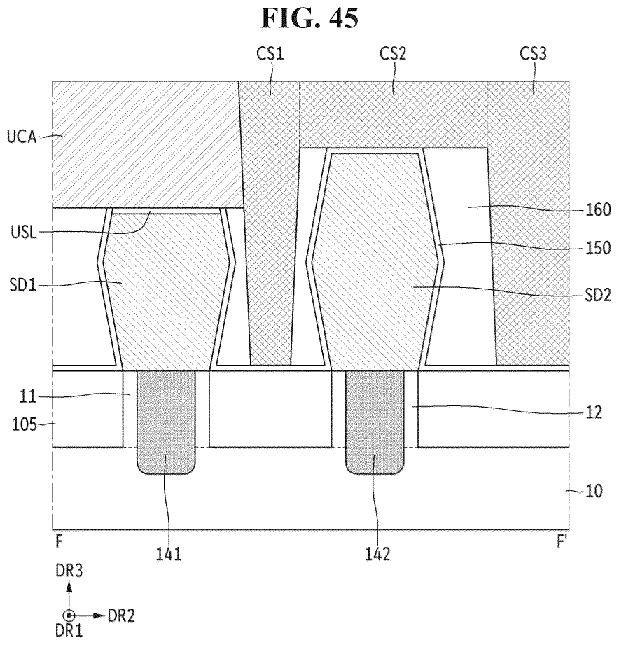

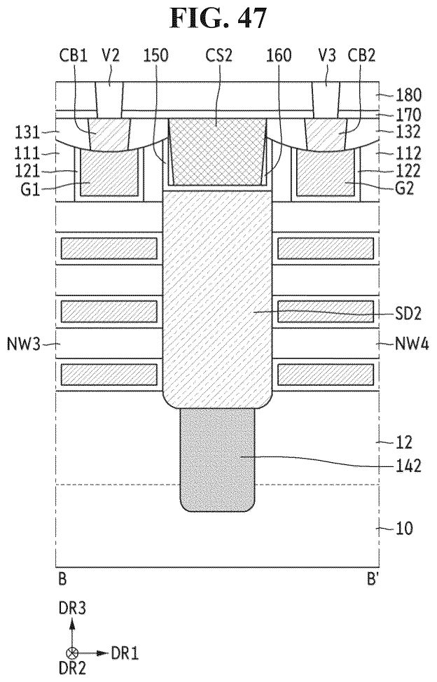

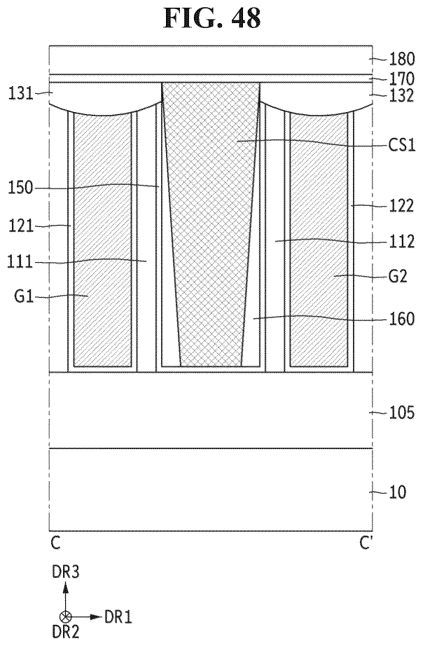

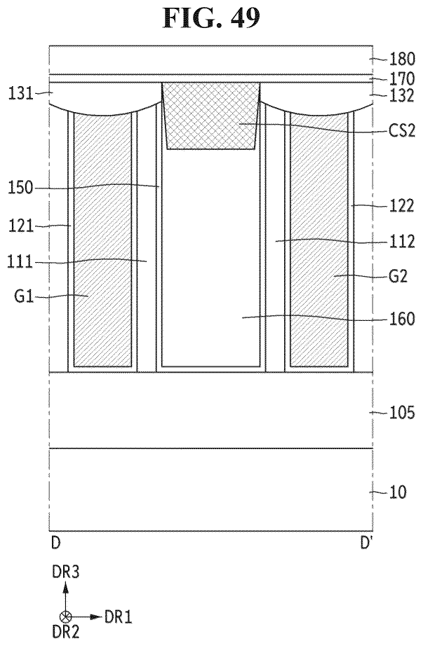

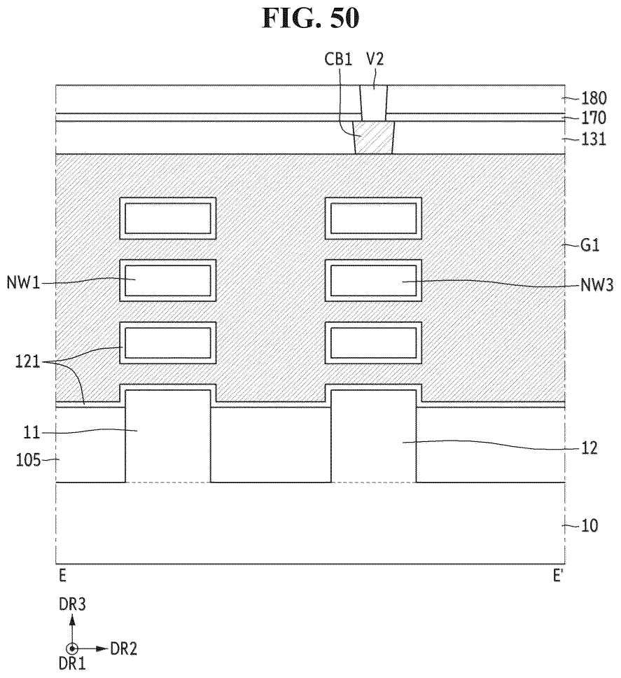

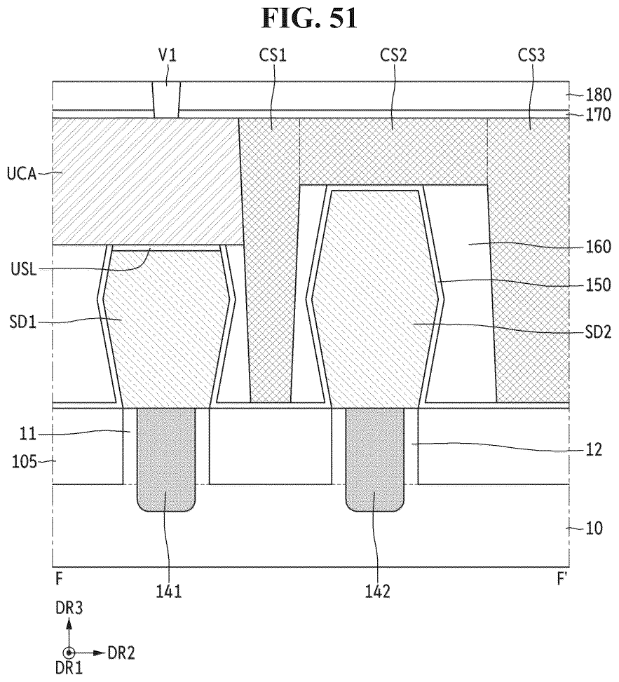

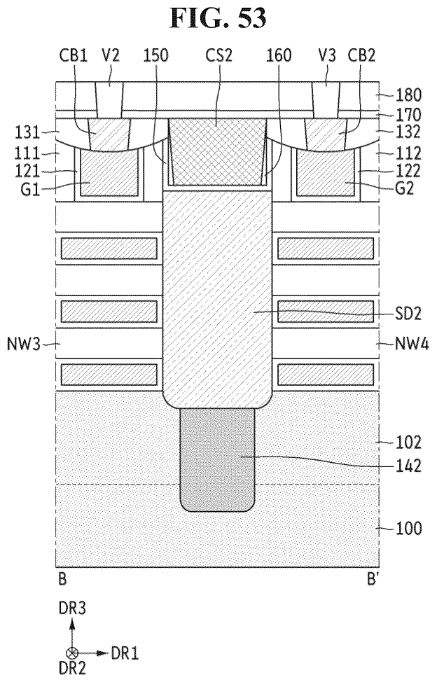

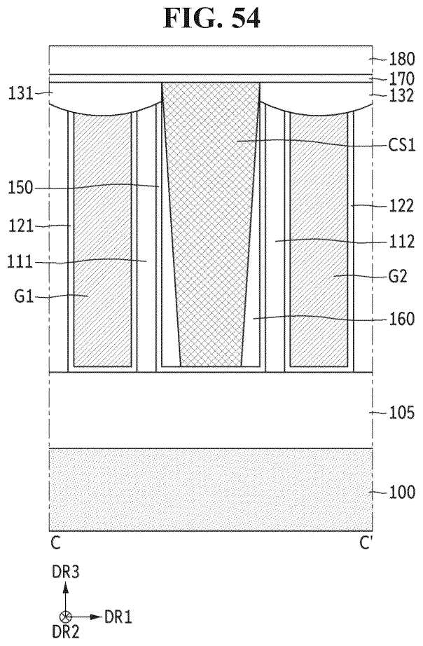

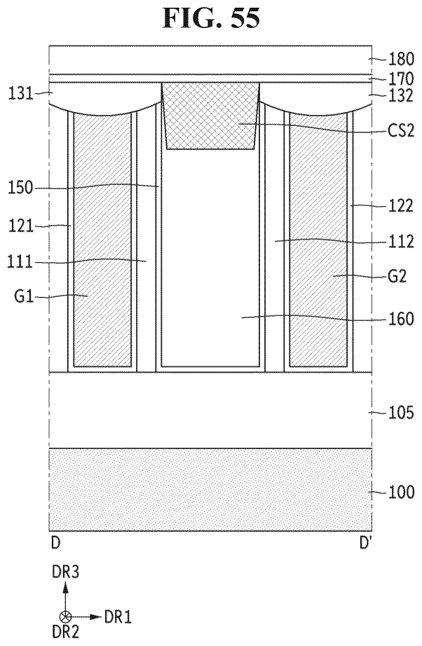

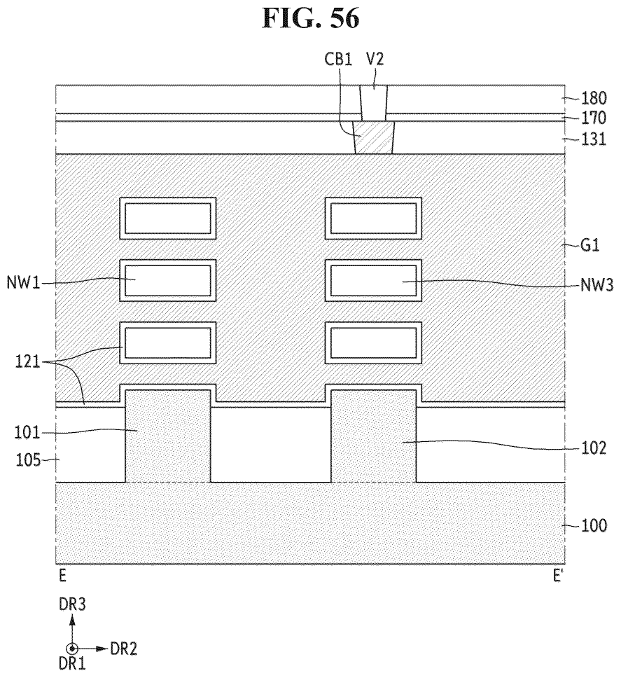

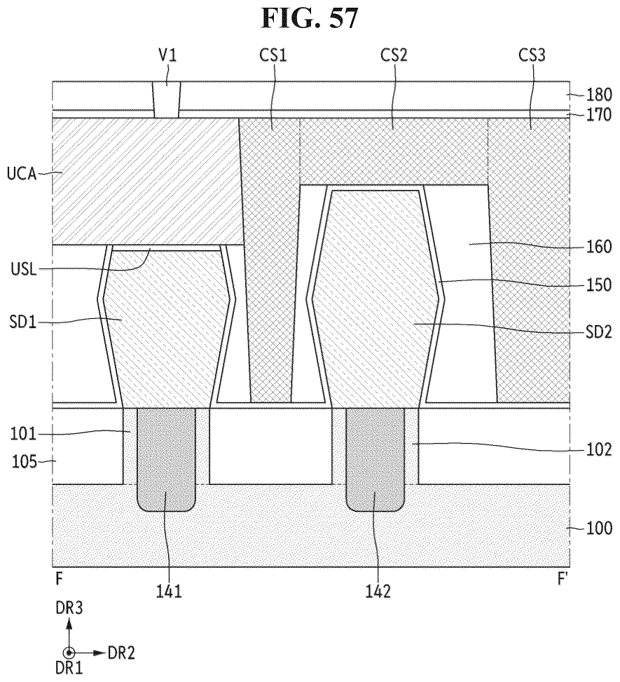

Hereinafter, a method for fabricating a semiconductor device according to some embodiments of the present disclosure will be described with reference to FIGS. 2 to 61.

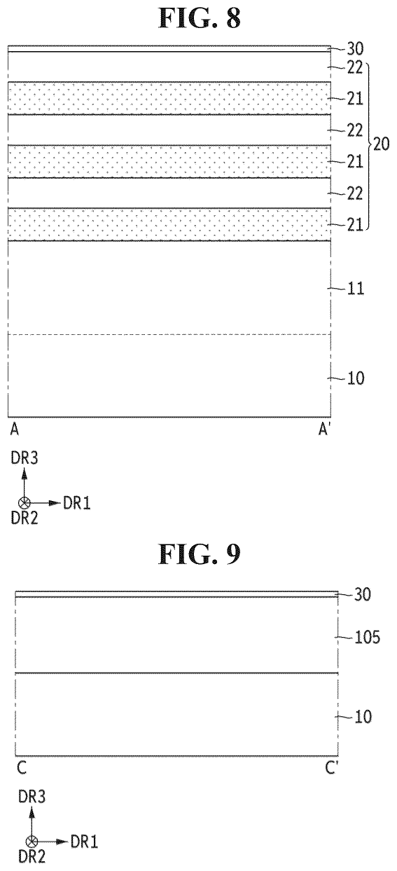

FIGS. 8 to 61 are views illustrating intermediate steps to describe a method for fabricating a semiconductor device according to some example embodiments of the present disclosure.

Referring to FIGS. 8 to 10, a substrate 10 may be provided. The substrate 10 may be a silicon substrate or a silicon-on-insulator (SOI). Alternatively, the substrate 10 may be formed of or include silicon germanium, silicon germanium on insulator (SGOI), indium antimonide, lead telluride, indium arsenide, indium phosphide, gallium arsenide, or gallium antimonide, but the present disclosure is not limited thereto.

Subsequently, a stacked structure 20 may be formed on the substrate 10. The stacked structure 20 may include a first semiconductor layer 21 and a second semiconductor layer 22, which are alternately stacked on an upper surface of the substrate 10. For example, the first semiconductor layer 21 may be formed on a lowermost portion of the stacked structure 20, and the second semiconductor layer 22 may be formed on an uppermost portion of the stacked structure 20, but the present disclosure is not limited thereto. In some other embodiments, the first semiconductor layer 21 may be also formed on the uppermost portion of the stacked structure 20. The first semiconductor layer 21 may be formed of or include, for example, silicon germanium (SiGe). The second semiconductor layer 22 may be formed of or include, for example, silicon (Si).

Then, a portion of the stacked structure 20 may be etched. A portion of the substrate 10 may be also etched while the stacked structure 20 is being etched. First and second active patterns 11 and 12 may be defined below the stacked structure 20 on the upper surface of the substrate 10 through the etching process. Each of the first and second active patterns 11 and 12 may be provided from the upper surface of the substrate 10 in the vertical direction DR3. Each of the first and second active patterns 11 and 12 may extend lengthwise in the first horizontal direction DR1. The second active pattern 12 may be spaced apart from the first active pattern 11 in the second horizontal direction DR2.

Subsequently, the field insulating layer 105 may be formed on the upper surface of the substrate 10. The field insulating layer 105 may surround sidewalls of each of the first and second active patterns 11 and 12. A pad oxide layer 30 may be formed to cover the upper surface of the field insulating layer 105, the exposed sidewalls of the first and second active patterns 11 and 12, and sidewalls and an upper surface of the stacked structure 20. For example, the pad oxide layer 30 may be formed to be conformal. The pad oxide layer 30 may be formed of or include, for example, silicon oxide (SiO₂).

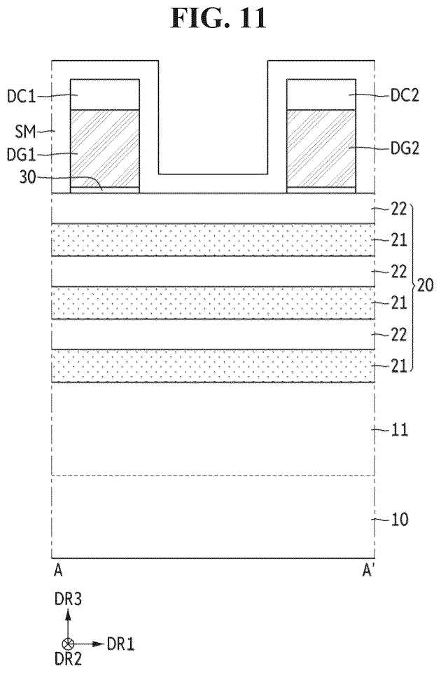

Referring to FIGS. 11 to 14, first and second dummy gates DG1 and DG2 and first and second dummy capping patterns DC1 and DC2, which are extended in the second horizontal direction DR2 on the pad oxide layer 30, may be formed on the stacked structure 20 and the field insulating layer 105. For example, the second dummy gate DG2 may be spaced apart from the first dummy gate DG1 in the first horizontal direction DR1. The first dummy capping pattern DC1 may be disposed on the first dummy gate DG1. The second dummy capping pattern DC2 may be disposed on the second dummy gate DG2. While the first and second dummy gates DG1 and DG2 and the first and second dummy capping patterns DC1 and DC2 are being formed, the remaining pad oxide layer 30 except a portion overlapped with each of the first and second dummy gates DG1 and DG2 in the vertical direction DR3 on the substrate 10 may be removed.

Subsequently, a spacer material layer SM may be formed to cover sidewalls of each of the first and second dummy gates DG1 and DG2, sidewalls and an upper surface of each of the first and second dummy capping patterns DC1 and DC2, the exposed sidewalls and upper surface of the stacked structure 20 and the upper surface of the field insulating layer 105. For example, the spacer material layer SM may be formed to be conformal. The spacer material layer SM may include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC) or their combination.

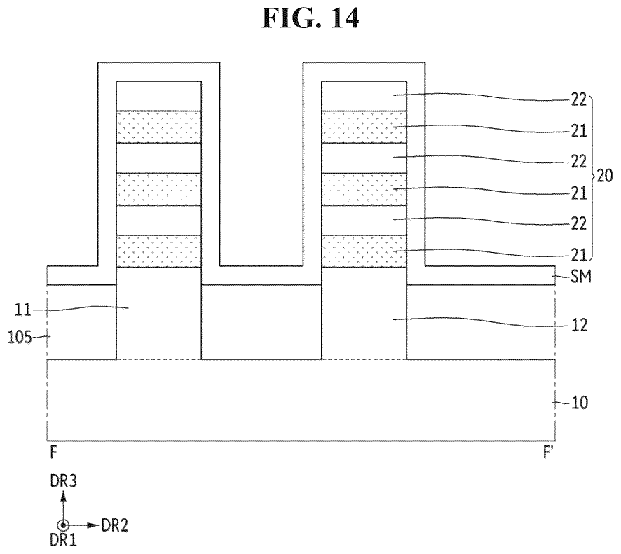

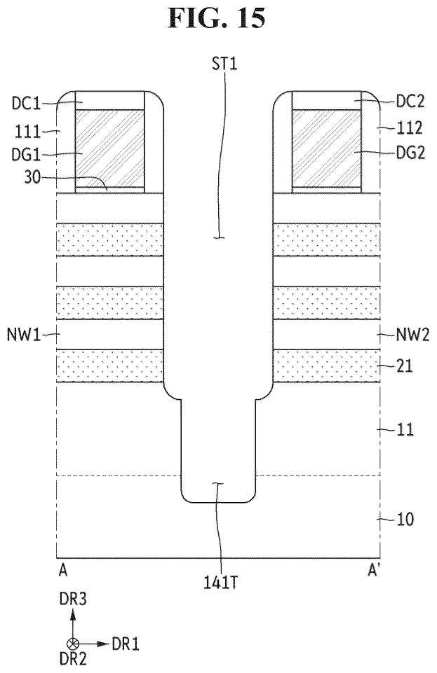

Referring to FIGS. 15 to 18, the stacked structure (e.g., stacked structure 20 of FIGS. 11 and 14) may be etched using the first and second dummy gates DG1 and DG2 and the first and second dummy capping patterns DC1 and DC2 as masks to form first and second source/drain trenches ST1 and ST2. The first source/drain trench ST1 may be formed between the first dummy gate DG1 and the second dummy gate DG2 on the first active pattern 11. The second source/drain trench ST2 may be formed between the first dummy gate DG1 and the second dummy gate DG2 on the second active pattern 12.

Also, a first sacrificial pattern trench 141T may be formed below the first source/drain trench ST1, and a second sacrificial pattern trench 142T may be formed below the second source/drain trench ST2. For example, the first sacrificial pattern trench 141T may be formed inside the first active pattern 11 and the substrate 10. Also, the second sacrificial pattern trench 142T may be formed inside the second active pattern 12 and the substrate 10. For example, the substrate 10 may be exposed as a lower surface of each of the first and second sacrificial pattern trenches 141T and 142T.

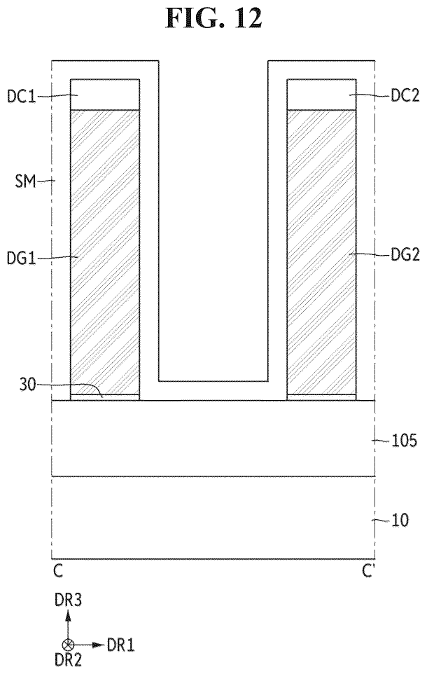

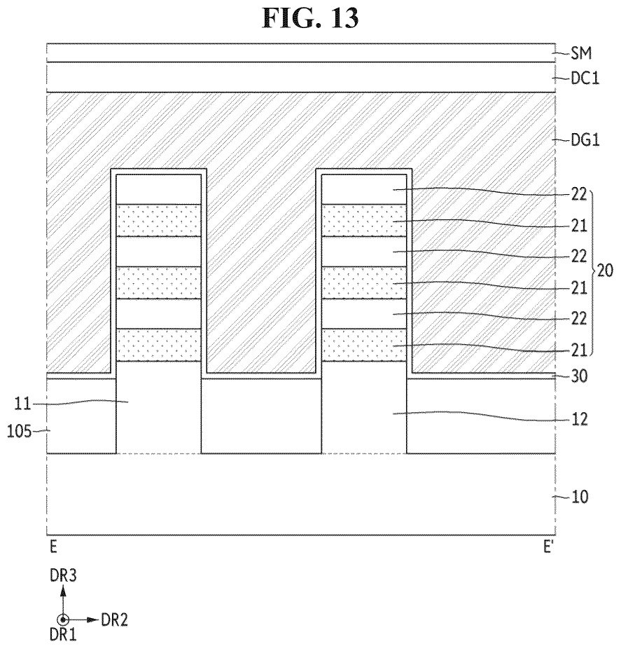

For example, while the first and second source/drain trenches ST1 and ST2 are being formed, a portion of each of the spacer material layer (e.g., spacer material layer SM of FIGS. 11 and 12) and the first and second dummy capping patterns DC1 and DC2, which are formed on the upper surface of each of the first and second dummy capping patterns DC1 and DC2, may be etched. The spacer material layer (e.g., spacer material layer SM of FIGS. 11 and 12) remaining on the sidewalls of each of the first and second dummy gates DG1 and DG2 may be defined as the first and second gate spacers 111 and 112.

After the first source/drain trench ST1 is formed, a second semiconductor layer (e.g., second semiconductor layer 22 of FIGS. 11 and 13) remaining below the first dummy gate DG1 on the first active pattern 11 may be defined as the first plurality of nanosheets NW1. After the first source/drain trench ST1 is formed, a second semiconductor layer (e.g., second semiconductor layer 22 of FIGS. 11 and 13) remaining below the second dummy gate DG2 on the first active pattern 11 may be defined as the second plurality of nanosheets NW2. After the second source/drain trench ST2 is formed, a second semiconductor layer (e.g., second semiconductor layer 22 of FIGS. 11 and 13) remaining below the first dummy gate DG1 on the second active pattern 12 may be defined as the third plurality of nanosheets NW3. After the second source/drain trench ST2 is formed, a second semiconductor layer (e.g., second semiconductor layer 22 of FIGS. 11 and 13) remaining below the second dummy gate DG2 on the second active pattern 12 may be defined as the fourth plurality of nanosheets NW4.

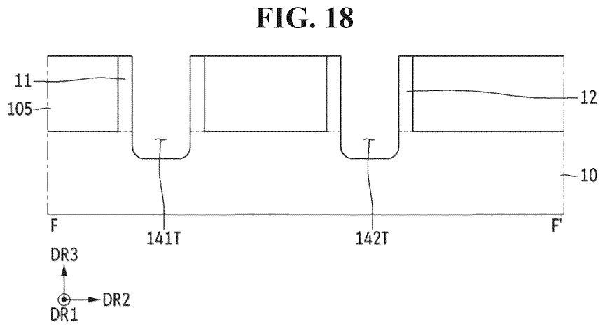

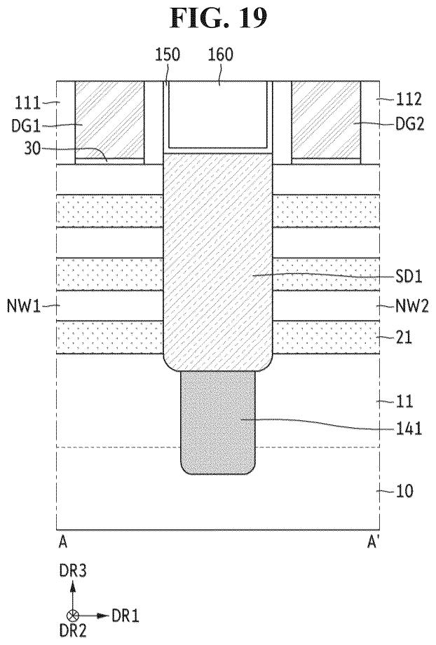

Referring to FIGS. 19 to 22, the first sacrificial pattern 141 may be formed inside the first sacrificial pattern trench (e.g., first sacrificial pattern trench 141T of FIGS. 15 and 18), and the second sacrificial pattern 142 may be formed inside the second sacrificial pattern trench (e.g., second sacrificial pattern trench 142T of FIGS. 15 and 18). For example, an upper surface of the first sacrificial pattern 141 may be formed to be lower than the uppermost surface of the first active pattern 11. Also, an upper surface of the second sacrificial pattern 142 may be formed to be lower than the uppermost surface of the second active pattern 12. Each of the first and second sacrificial patterns 141 and 142 may be formed of or include, for example, silicon germanium (SiGe).

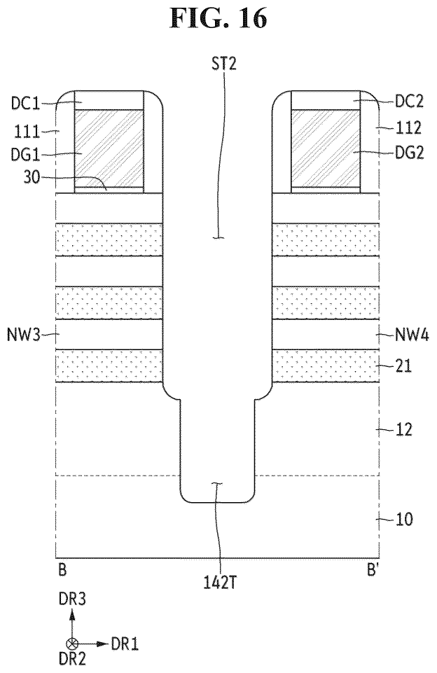

Subsequently, the first drain region D1 may be formed inside the first source/drain trench (e.g., first source/drain trench ST1 of FIG. 15), and the second source region S2 may be formed inside the second source/drain trench (e.g., second source/drain trench ST2 of FIG. 16). For example, the lower surface of the first source/drain region SD1 may be in contact with the upper surface of the first sacrificial pattern 141. Also, the lower surface of the second source/drain region SD2 may be in contact with the upper surface of the second sacrificial pattern 142.

Subsequently, the first etching stop layer 150 may be formed on the exposed surface of the field insulating layer 105, the expose upper surface of each of the first and second dummy capping patterns (e.g., first and second dummy capping patterns DC1 and DC2 of FIGS. 15 to 17) and the exposed surface of each of the first and second source regions S1 and S4. Then, the first upper interlayer insulating layer 160 may be formed on the first etching stop layer 150. Subsequently, the upper surface of each of the first and second dummy gates DG1 and DG2 may be exposed through a planarization process.

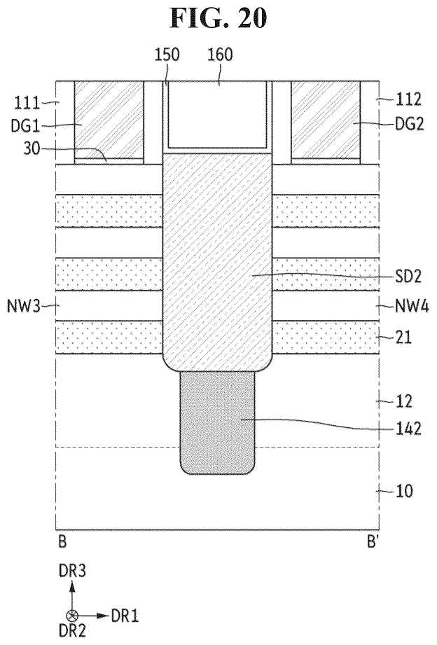

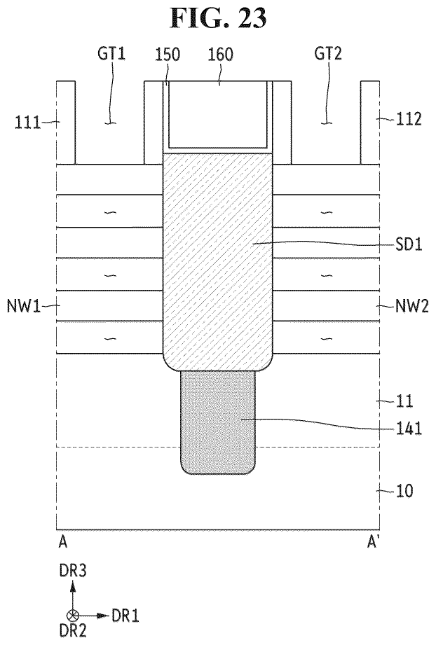

Referring to FIGS. 23 to 26, each of the first and second dummy gates (e.g., first and second dummy gates DG1 and DG2 of FIGS. 19 to 21), the pad oxide layer (e.g., pad oxide layer 30 of FIGS. 19 to 21) and the first semiconductor layer (e.g., first semiconductor layer 21 of FIGS. 19 and 20) may be etched. A portion where the first dummy gate (e.g., first dummy gate DG1 of FIGS. 19 to 21), the pad oxide layer (e.g., pad oxide layer 30 of FIGS. 19 to 21) and the first semiconductor layer (e.g., first semiconductor layer 21 of FIGS. 19 and 20) are etched may be defined as a first gate trench GT1. Also, a portion where the second dummy gate (e.g., second dummy gate DG2 of FIGS. 19 to 21), the pad oxide layer (e.g., pad oxide layer 30 of FIGS. 19 to 21) and the first semiconductor layer (e.g., first semiconductor layer 21 of FIGS. 19 and 20) are etched may be defined as a second gate trench GT2.

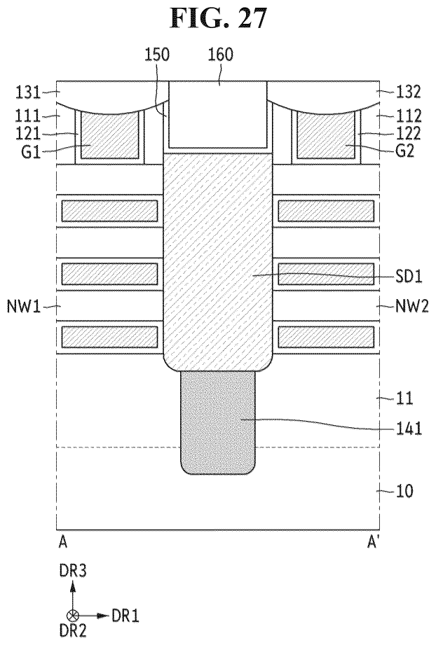

Referring to FIGS. 27 to 30, the first gate insulating layer 121, the first gate electrode G1 and the first capping pattern 131 may be sequentially formed inside the first gate trench (e.g., first gate trench GT1 of FIGS. 23 to 25). Also, the second gate insulating layer 122, the second gate electrode G2 and the second capping pattern 132 may be sequentially formed inside the second gate trench (e.g., second gate trench GT2 of FIGS. 23 to 25). For example, the first gate electrode G1 may surround each of the plurality of first and third plurality of nanosheets NW1 and NW3. The second gate electrode G2 may surround each of the plurality of second and fourth plurality of nanosheets NW2 and NW4.

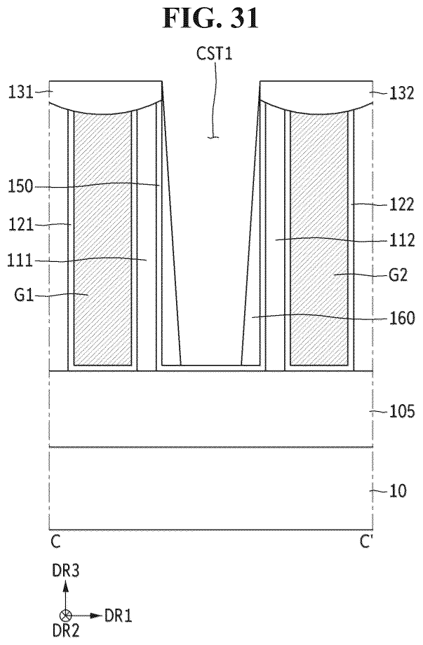

Referring to FIGS. 31 to 33, each of a first contact separating trench CST1 and a second contact separating trench CST2 may be formed between the first gate electrode G1 and the second gate electrode G2. The first contact separating trench CST1 may be formed between the first source/drain region SD1 and the second source/drain region SD2. The second contact separating trench CST2 may be spaced apart from the second source/drain region SD2 in the second horizontal direction DR2. For example, the second source/drain region SD2 may be formed between the first contact separating trench CST1 and the second contact separating trench CST2.

For example, each of the first and second contact separating trenches CST1 and CST2 may be extended to the upper surface of the first etching stop layer 150 formed on the upper surface of the field insulating layer 105 by penetrating through the first upper interlayer insulating layer 160 in the vertical direction DR3. For example, the first etching stop layer 150 disposed on the upper surface of the field insulating layer 105 may be exposed through each of the first and second contact separating trenches CST1 and CST2. For example, the first etching stop layer 150 disposed on the sidewalls of each of the first and second source/drain regions SD1 and SD2 in the second horizontal direction DR2 may be spaced apart from each of the first and second contact separating trenches CST1 and CST2 in the second horizontal direction DR2.

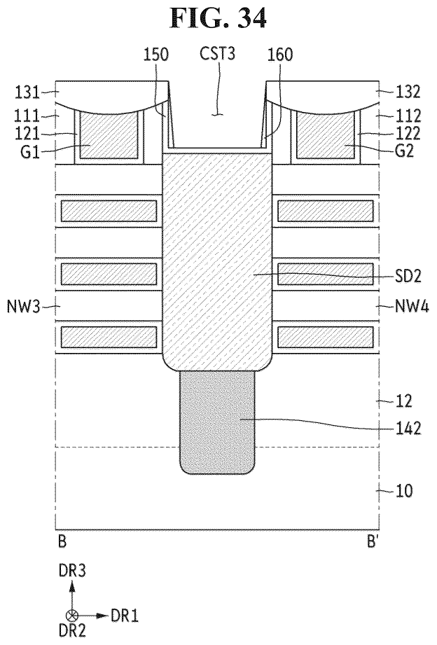

Referring to FIGS. 34 to 36, a third contact separating trench CST3 may be formed between the first gate electrode G1 and the second gate electrode G2. The third contact separating trench CST3 may be formed on the upper surface of the second source/drain region SD2. The third contact separating trench CST3 may connect the first contact separating trench CST1 with the second contact separating trench CST2. For example, the first to third contact separating trenches CST1, CST2 and CST3 may be integrally formed.

For example, a bottom surface of the third contact separating trench CST3 may be formed to be higher than that of each of the first and second contact separating trenches CST1 and CST2. For example, the third contact separating trench CST3 may be extended to the upper surface of the first etching stop layer 150 formed on the upper surface of the second source/drain region SD2 by penetrating through the first upper interlayer insulating layer 160 in the vertical direction DR3. That is, the first etching stop layer 150 formed on the upper surface of the second source/drain region SD2 may be exposed through the third contact separating trench CST3.

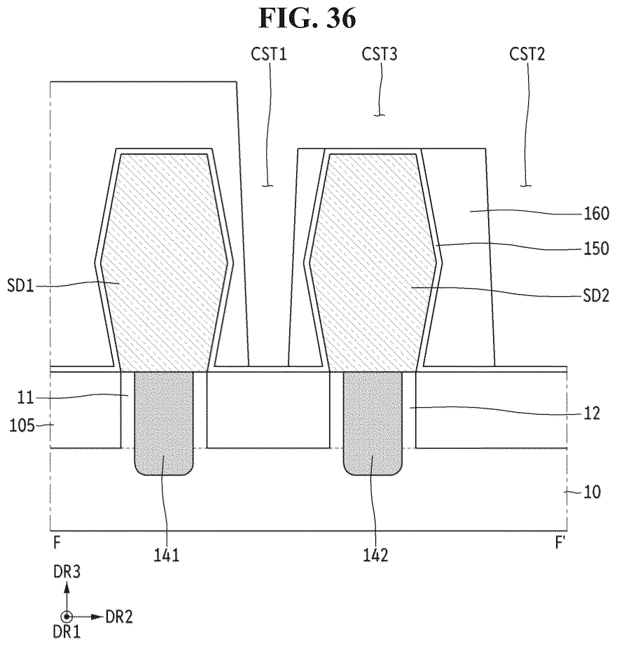

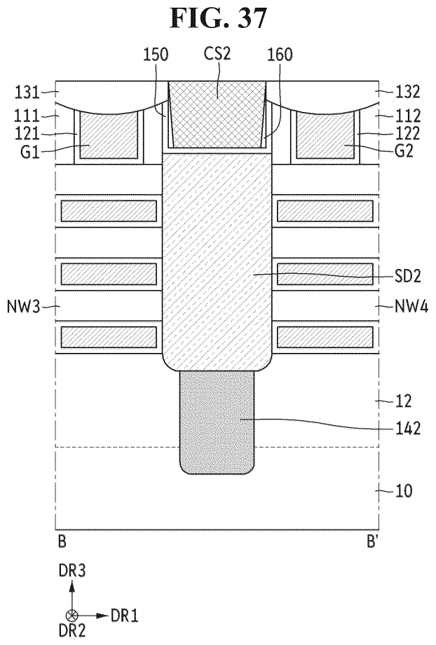

Referring to FIGS. 37 to 40, the first contact separating layer CS1 may be formed inside the first contact separating trench (e.g., first contact separating trench CST1 of FIG. 36), the third contact separating layer CS3 may be formed inside the second contact separating trench (e.g., second contact separating trench CST2 of FIG. 36), and the second contact separating layer CS2 may be formed inside the third contact separating trench (e.g., third contact separating trench CST3 of FIGS. 34 to 36). For example, the first to third contact separating layers CS1, CS2 and CS3 may be formed through the same fabricating process. For example, the upper surfaces of the first to third contact separating layers CS1, CS2 and CS3 may be formed on the same plane.

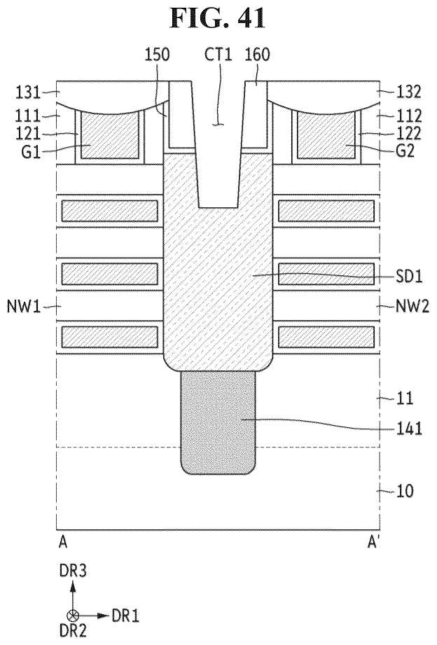

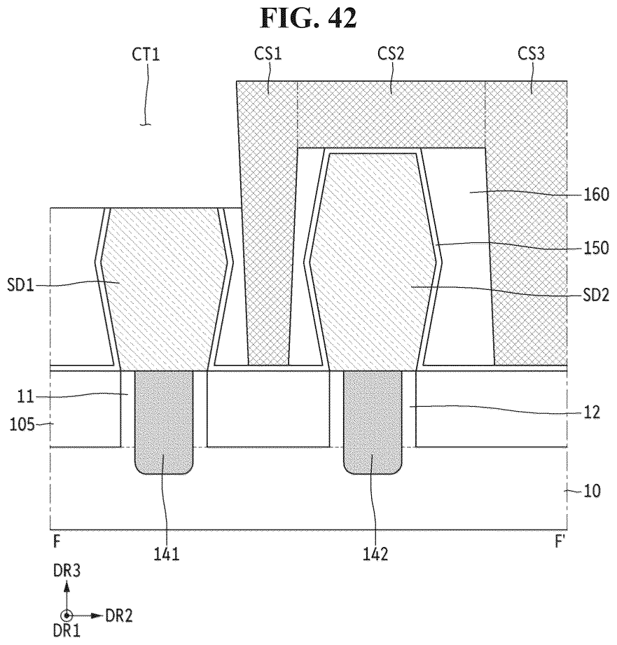

Referring to FIGS. 41 and 42, the first contact trench CT1 may be formed on the first source/drain region SD1 between the first gate electrode G1 and the second gate electrode G2. The first contact trench CT1 may be extended into the first source/drain region SD1 by penetrating through the first upper interlayer insulating layer 160 and the first etching stop layer 150 in the vertical direction DR3. For example, the sidewalls of the first contact separating layer CS1 in the second horizontal direction DR2 may be exposed through the first contact trench CT1. For example, a bottom surface of the first contact trench CT1 may be formed to be higher than that of each of the first and third contact separating layers CS1 and CS3. For example, the bottom surface of the first contact trench CT1 may be formed to be lower than that of the second contact separating layer CS2.

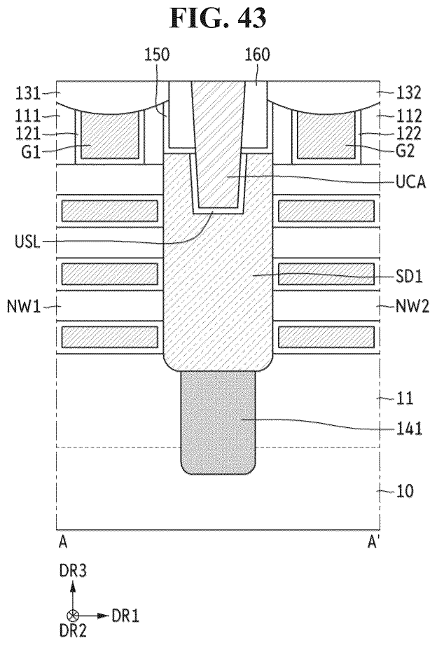

Referring to FIGS. 43 to 45, the upper source/drain contact UCA may be formed inside the first contact trench (e.g., first contact trench CT1 of FIGS. 41 and 42). For example, the upper source/drain contact UCA may be in contact with the sidewall of the first contact separating layer CS1 in the second horizontal direction DR2. For example, the upper surface of the upper source/drain contact UCA may be formed on the same plane as the upper surfaces of the first to third contact separating layers CS1, CS2 and CS3. The upper silicide layer USL may be formed between the first source/drain region SD1 and the upper source/drain contact UCA. Also, the first gate contact CB1 connected to the first gate electrode G1 by penetrating through the first capping pattern 131 in the vertical direction DR3 may be formed. The second gate contact CB2 connected to the second gate electrode G2 by penetrating through the second capping pattern 132 in the vertical direction DR3 may be formed.

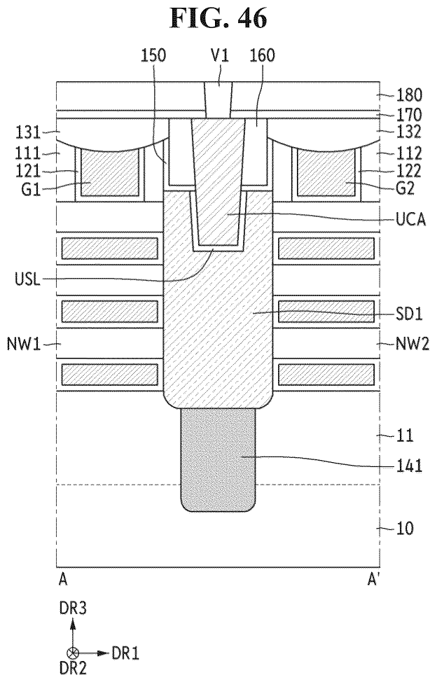

Referring to FIGS. 46 to 51, the second etching stop layer 170 and the second upper interlayer insulating layer 180 may be sequentially formed on the upper surface of each of the first upper interlayer insulating layer 160, the first and second capping patterns 131 and 132, the upper source/drain contact UCA, the first and second gate contacts CB1 and CB2, and the first to third contact separating layers CS1, CS2 and CS3. Subsequently, the first via V1 connected to the upper source/drain contact UCA by penetrating through the second etching stop layer 170 and the second upper interlayer insulating layer 180 in the vertical direction DR3 may be formed. The second via V2 connected to the first gate contact CB1 by penetrating through the second etching stop layer 170 and the second upper interlayer insulating layer 180 in the vertical direction DR3 may be formed. The third via V3 connected to the second gate contact CB2 by penetrating through the second etching stop layer 170 and the second upper interlayer insulating layer 180 in the vertical direction DR3 may be formed.

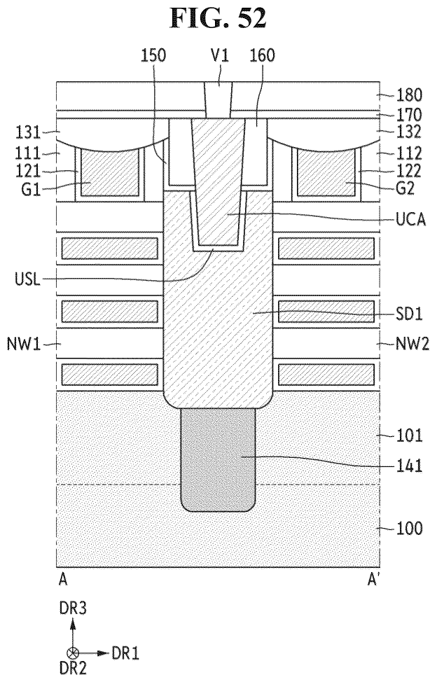

Referring to FIGS. 52 to 57, the substrate (e.g., substrate 10 of FIGS. 46 to 51), the first active pattern (e.g., first active pattern 11 of FIGS. 46 to 51) and the second active pattern (e.g., second active pattern 12 of FIGS. 46 to 51) may be respectively etched. Subsequently, the first insulating pattern 101 may be formed on a portion where the first active pattern (e.g., first active pattern 11 of FIGS. 46 to 51) is etched, and the second insulating pattern 102 may be formed on a portion where the second insulating pattern (e.g., second active pattern 12 of FIGS. 46 to 51) is etched. Also, the lower interlayer insulating layer 100 may be formed on a portion where the substrate (e.g., substrate 10 of FIGS. 46 to 51) is etched.

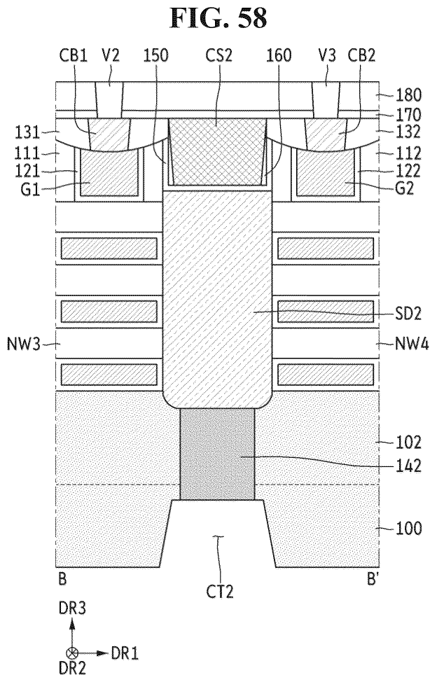

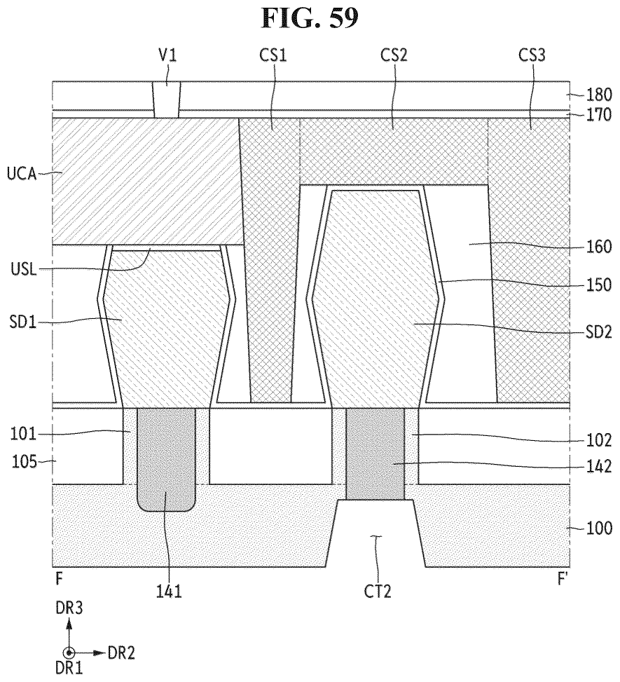

Referring to FIGS. 58 and 59, the second contact trench CT2 may be formed below the second sacrificial pattern 142. For example, the second contact trench CT2 may be extended to the lower surface of the second sacrificial pattern 142 by penetrating through the lower interlayer insulating layer 100 in the vertical direction DR3. That is, the lower surface of the second sacrificial pattern 142 may be exposed through the second contact trench CT2.

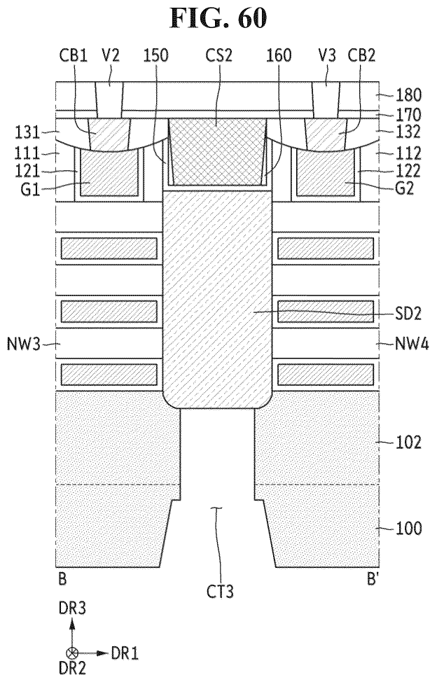

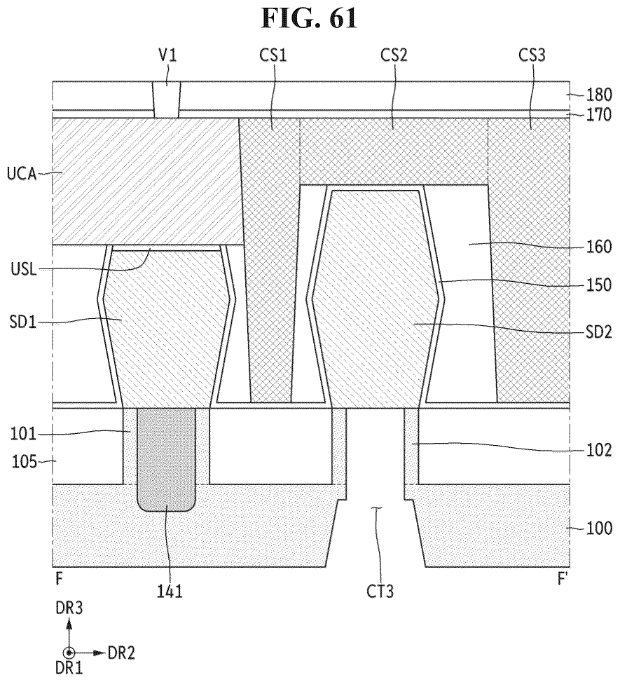

Referring to FIGS. 60 and 61, the second sacrificial pattern 142 may be etched through the second contact trench (e.g., second contact trench CT2 of FIGS. 58 and 59). For this reason, the lower surface of the second source/drain region SD2 may be exposed. The portion where the second sacrificial pattern (e.g., second sacrificial pattern 142 of FIGS. 58 and 59) is etched and the second contact trench (e.g., second contact trench CT2 of FIGS. 58 and 59) may be defined as the third contact trench CT3.

Referring to FIG. 2 to FIG. 7, the lower source/drain contact BCA may be formed inside the third contact trench (e.g., third contact trench CT3 of FIGS. 60 and 61). Also, the lower silicide layer BSL may be formed between the second source/drain region SD2 and the lower source/drain contact BCA. The semiconductor device shown in FIG. 2 to FIG. 7 may be fabricated through such a fabricating process.

In the method for fabricating a semiconductor device according to some embodiments of the present disclosure, the second contact separating layer CS2 may be formed on the upper surface of the second source/drain region SD2 to which the lower source/drain contact BCA is electrically connected. In the process of etching the first upper interlayer insulating layer 160 to form the upper source/drain contact UCA electrically connected to the first source/drain region SD1, the second source/drain region SD2 is not exposed by the second contact separating layer CS2. For this reason, the method for fabricating a semiconductor device according to some embodiments of the present disclosure may make sure of reliability of the second source/drain region SD2 electrically connected to the lower source/drain contact BCA.

In the semiconductor device according to some embodiments of the present disclosure, which is fabricated by the method for fabricating a semiconductor device as described above, the second contact separating layer CS2 may be disposed on the upper surface of the second source/drain region SD2 to which the lower source/drain contact BCA is electrically connected. In addition, the first contact separating layer CS1 and the third contact separating layer CS3 may be disposed on both sidewalls of the second source/drain region SD2 in the second horizontal direction DR2. That is, the second contact separating layer CS2 may be disposed between the first contact separating layer CS1 and the third contact separating layer CS3.

Also, in the semiconductor device according to some embodiments of the present disclosure, which is fabricated by the method for fabricating a semiconductor device as described above, the lower surface of the second contact separating layer CS2 may be formed to be higher than each of the lower surface of the first contact separating layer CS1 and the lower surface of the third contact separating layer CS3. Also, the lower surface of the upper source/drain contact UCA may be formed to be lower than the lower surface of the second contact separating layer CS2. Also, the lower surface of the upper source/drain contact UCA may be formed to be higher than each of the lower surface of the first contact separating layer CS1 and the lower surface of the third contact separating layer CS3, respectively.

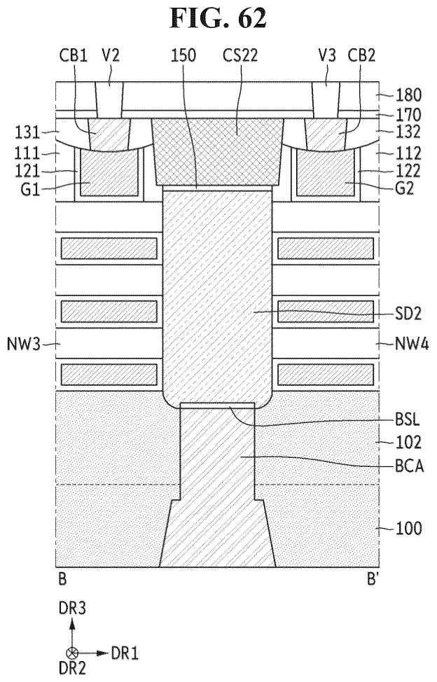

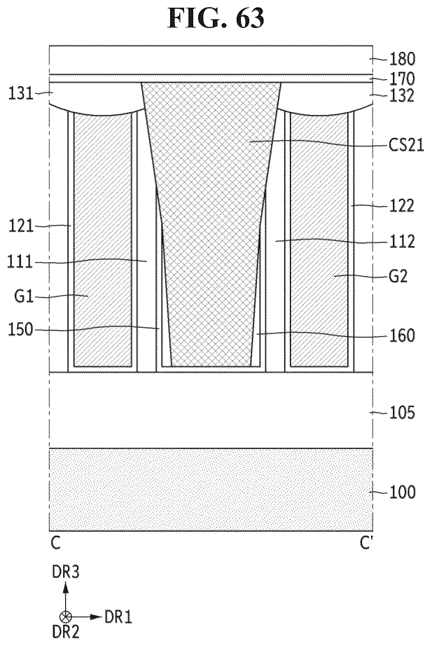

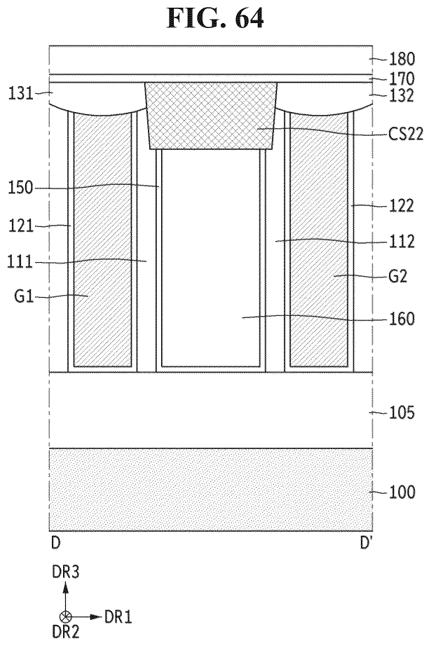

Hereinafter, the semiconductor device according to some other embodiments of the present disclosure will be described with reference to FIGS. 62 to 64. The following description will be based on a difference from the semiconductor device shown in FIGS. 1 to 7.

FIGS. 62 to 64 are cross-sectional views illustrating a semiconductor device according to some other example embodiments of the present disclosure.

Referring to FIGS. 62 to 64 in a semiconductor device according to some other embodiments of the present disclosure, first and second contact separating layers CS21 and CS22 may be in contact with the first and second gate spacers 111 and 112, respectively.

For example, at least a portion of each of the first and second contact separating layers CS21 and CS22 may overlap each of the first and second gate spacers 111 and 112 in the vertical direction DR3. For example, the sidewalls of each of the first and second contact separating layers CS21 and CS22 in the first horizontal direction DR1 may be in contact with the first and second gate spacers 111 and 112, respectively. For example, the sidewalls of each of the first and second contact separating layers CS21 and CS22 in the first horizontal direction DR1 may be in contact with the first and second capping patterns 131 and 132, respectively. For example, at least a portion of the lower surface of the second contact separating layer CS22 may be in contact with the first and second gate spacers 111 and 112, respectively.

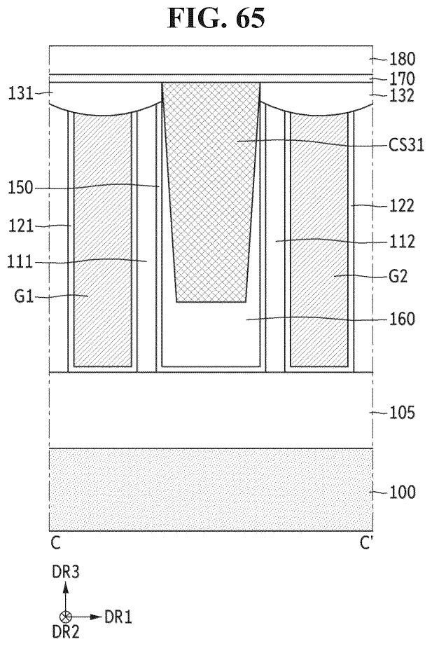

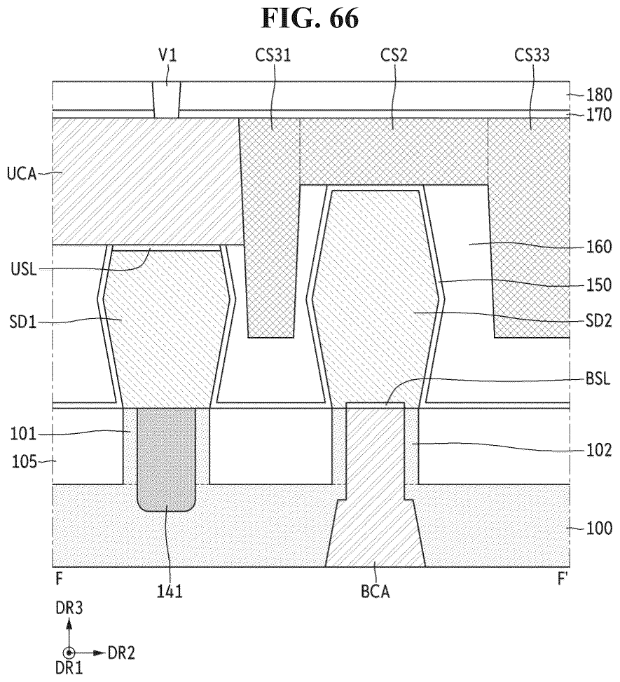

Hereinafter, a semiconductor device according to some other embodiments of the present disclosure will be described with reference to FIGS. 65 and 66. The following description will be based on a difference from the semiconductor device shown in FIGS. 1 to 7.

FIGS. 65 and 66 are cross-sectional views illustrating a semiconductor device according to some other example embodiments of the present disclosure.

Referring to FIGS. 65 and 66, in the semiconductor device according to some other embodiments of the present disclosure, a lower surface of a first contact separating layer CS31 and a lower surface of a third contact separating layer CS33 are not in contact with the first etching stop layer 150, respectively.

For example, the lower surface of the first contact separating layer CS31 may be spaced apart from the first etching stop layer 150 disposed on the upper surface of the field insulating layer 105 in the vertical direction DR3. Also, the lower surface of the third contact separating layer CS33 may be spaced apart from the first etching stop layer 150 disposed on the upper surface of the field insulating layer 105 in the vertical direction DR3. For example, the lower surface of each of the first and third contact separating layers CS31 and CS33 may be in contact with the first upper interlayer insulating layer 160. For example, the lower surface of each of the first and third contact separating layers CS31 and CS33 may be formed to be lower than the lower surface of the upper source/drain contact UCA.

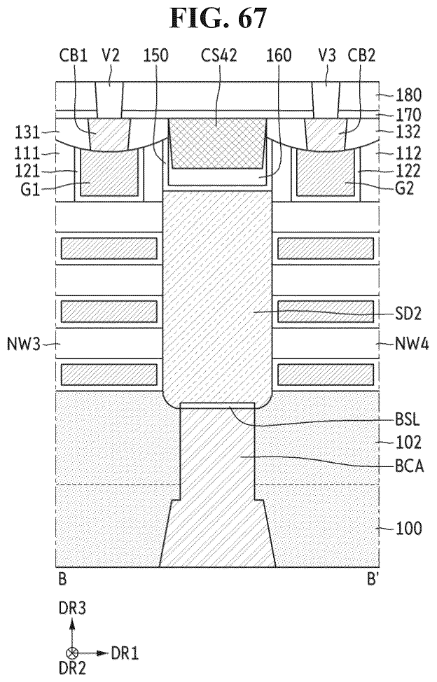

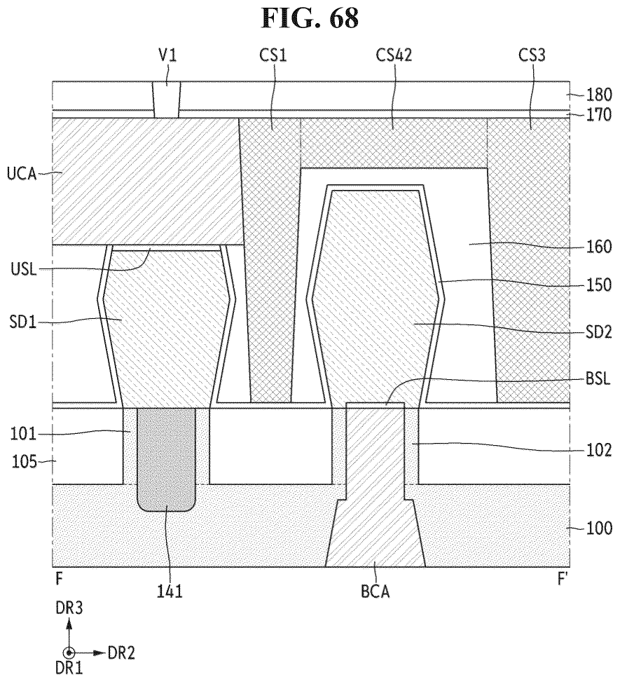

Hereinafter, a semiconductor device according to some other embodiments of the present disclosure will be described with reference to FIGS. 67 and 68. The following description will be based on a difference from the semiconductor device shown in FIGS. 1 to 7.

FIGS. 67 and 68 are cross-sectional views illustrating a semiconductor device according to some other example embodiments of the present disclosure.

Referring to FIGS. 67 and 68, in the semiconductor device according to some other embodiments of the present disclosure, a lower surface of a second contact separating layer CS42 is not in contact with the first etching stop layer 150.

For example, the lower surface of the second contact separating layer CS42 may be spaced apart from the first etching stop layer 150 disposed on the upper surface of the second source/drain region SD2 in the vertical direction DR3. For example, the lower surface of the second contact separating layer CS42 may be in contact with the first upper interlayer insulating layer 160. For example, the lower surface of the second contact separating layer CS42 may be formed to be higher than the lower surface of each of the first and third contact separating layers CS1 and CS3. For example, the lower surface of the second contact separating layer CS42 may be formed to be higher than the lower surface of the upper source/drain contact UCA.

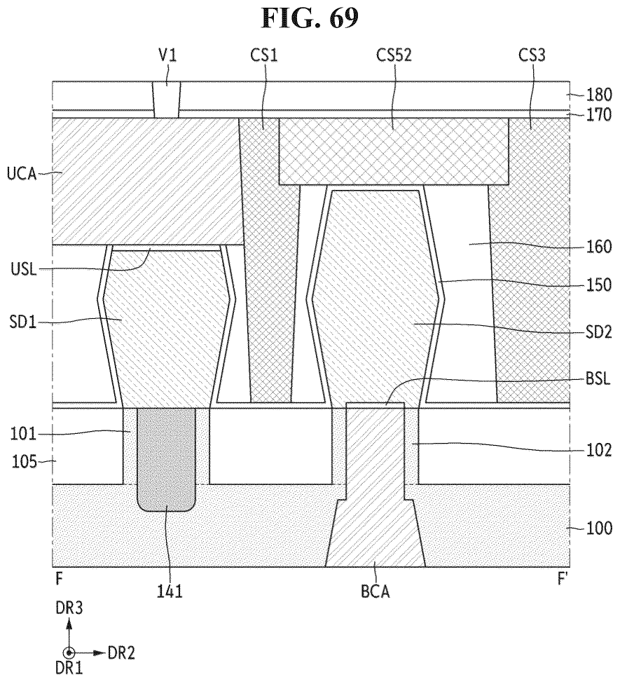

Hereinafter, a semiconductor device according to some other embodiments of the present disclosure will be described with reference to FIG. 69. The following description will be based on a difference from the semiconductor device shown in FIGS. 1 to 7.

FIG. 69 is a cross-sectional view illustrating a semiconductor device according to some other example embodiments of the present disclosure.

Referring to FIG. 69, in the semiconductor device according to some other embodiments of the present disclosure, a second contact separating layer CS52 may be formed of or include a material different from that of each of the first and third contact separating layers CS1 and CS3.

For example, the second contact separating layer CS52 may be formed of or include silicon nitride (SiN), silicon oxynitride (SiON), silicon carbonitride (SiCN), silicon oxycarbide (SiOC), or silicon oxycarbonitride (SiOCN). For example, each of the first and third contact separating layers CS1 and CS3 may be formed of or include a material different from that of the second contact separating layer CS52 among silicon nitride (SiN), silicon oxynitride (SiON), silicon carbonitride (SiCN), silicon oxycarbide (SiOC) or silicon oxycarbonitride (SiOCN). For example, the first contact separating layer CS1 and the third contact separating layer CS3 may be formed of or include the same material. For example, each of the first to third contact separating layers CS1, CS52 and CS3 may be formed of or include a material different from that of the first upper interlayer insulating layer 160.

For example, at least a portion of the second contact separating layer CS52 may overlap each of the first and third contact separating layers CS1 and CS3 in the vertical direction DR3. For example, sidewalls of the second contact separating layer CS52 in the second horizontal direction DR2 may be in contact with each of the first and third contact separating layers CS1 and CS3. For example, at least a portion of a lower surface of the second contact separating layer CS52 may be in contact with each of the first and third contact separating layers CS1 and CS3. For example, an upper surface of the second contact separating layer CS52 may be formed on the same plane as each of the upper surfaces of the first and third contact separating layers CS1 and CS3.

Although the embodiments according to the present disclosure have been described with reference to the accompanying drawings, it will be apparent to those skilled in the art that the present disclosure can be fabricated in various forms without being limited to the above-described embodiments, and can be embodied in other specific forms without departing from technical spirits and essential characteristics of the present disclosure. Thus, the above embodiments are to be considered in all respects as illustrative and not restrictive.

What is claimed is:

1. A semiconductor device comprising:
a lower interlayer insulating layer;
a first insulating pattern extended in a first horizontal direction on an upper surface of the lower interlayer insulating layer;
a second insulating pattern extended in the first horizontal direction on the upper surface of the lower interlayer insulating layer, the second insulating pattern spaced apart from the first insulating pattern in a second horizontal direction different from the first horizontal direction;
a first plurality of nanosheets stacked to be spaced apart from each other in a vertical direction on the first insulating pattern;
a second plurality of nanosheets stacked to be spaced apart from each other in the vertical direction on the second insulating pattern;
a field insulating layer surrounding sidewalls of the first and second insulating patterns on the upper surface of the lower interlayer insulating layer;
a gate electrode extended in the second horizontal direction on the first and second insulating patterns, the gate electrode surrounding each of the first and second plurality of nanosheets;
a first source/drain region disposed on one side of the gate electrode on the first insulating pattern;
a second source/drain region disposed on the one side of the gate electrode on the second insulating pattern;
an upper interlayer insulating layer covering the first and second source/drain regions on an upper surface of the field insulating layer;
a first contact separating layer disposed inside the upper interlayer insulating layer between the first and second source/drain regions, the first contact separating layer including a material different from a material of the upper interlayer insulating layer;
a second contact separating layer disposed inside the upper interlayer insulating layer on an upper surface of the second source/drain region, a lower surface of the second contact separating layer being at a level higher than a level of a lower surface of the first contact separating layer, the second contact separating layer including a material different from the material of the upper interlayer insulating layer, the second contact separating layer being in contact with the first contact separating layer; and
an upper source/drain contact electrically connected to the first source/drain region by penetrating through the upper interlayer insulating layer in the vertical direction, the upper source/drain contact being in contact with a sidewall of the first contact separating layer in the first horizontal direction.

2. The semiconductor device of claim 1, wherein an upper surface of the first contact separating layer is on the same plane as an upper surface of the second contact separating layer.

3. The semiconductor device of claim 1, wherein a lower surface of the upper source/drain contact is at a level higher than a level of the lower surface of the first contact separating layer.

4. The semiconductor device of claim 1, wherein a lower surface of the upper source/drain contact is at a level lower than a level of the lower surface of the second contact separating layer.

5. The semiconductor device of claim 1, further comprising a lower source/drain contact electrically connected to the second source/drain region by penetrating through the lower interlayer insulating layer and the second insulating pattern in the vertical direction.

6. The semiconductor device of claim 5, wherein the lower source/drain contact overlaps the second contact separating layer in the vertical direction.

7. The semiconductor device of claim 1, further comprising:
a sacrificial pattern disposed below the first source/drain region, a sidewall of the sacrificial pattern surrounded by the first insulating pattern.

8. The semiconductor device of claim 1, further comprising:
an etching stop layer disposed between the upper surface of the field insulating layer and the upper interlayer insulating layer,
wherein the lower surface of the first contact separating layer is in contact with the etching stop layer disposed on the upper surface of the field insulating layer.

9. The semiconductor device of claim 1, further comprising:
an etching stop layer in contact with a sidewall and the upper surface of the second source/drain region in the second horizontal direction,
wherein the lower surface of the second contact separating layer is in contact with the etching stop layer disposed on the upper surface of the second source/drain region.

10. The semiconductor device of claim 1, wherein the material of the second contact separating layer is the same as the material of the first contact separating layer.

11. The semiconductor device of claim 1, further comprising:
a gate spacer disposed between a sidewall of the gate electrode in the second horizontal direction and the upper interlayer insulating layer,
wherein at least a portion of the first contact separating layer overlaps the gate spacer in the vertical direction.

12. The semiconductor device of claim 11, wherein at least a portion of the second contact separating layer overlaps the gate spacer in the vertical direction.

13. A semiconductor device comprising:
a lower interlayer insulating layer;
a first insulating pattern extended in a first horizontal direction on an upper surface of the lower interlayer insulating layer;
a second insulating pattern extended in the first horizontal direction on the upper surface of the lower interlayer insulating layer, the second insulating pattern spaced apart from the first insulating pattern in a second horizontal direction different from the first horizontal direction;
a field insulating layer surrounding sidewalls of the first and second insulating patterns on the upper surface of the lower interlayer insulating layer;
a gate electrode extended in the second horizontal direction on the first and second insulating patterns;
a first source/drain region disposed on one side of the gate electrode on the first insulating pattern;
a second source/drain region disposed on the one side of the gate electrode on the second insulating pattern;
an upper interlayer insulating layer covering the first and second source/drain regions on an upper surface of the field insulating layer;
an etching stop layer disposed between the upper surface of the field insulating layer and the upper interlayer insulating layer, the etching stop layer being in contact with a sidewall and an upper surface of the second source/drain region in the second horizontal direction;
a first contact separating layer disposed inside the upper interlayer insulating layer between the first and second source/drain regions, the first contact separating layer including a material different from a material of the upper interlayer insulating layer;
a second contact separating layer disposed inside the upper interlayer insulating layer on the upper surface of the second source/drain region, a lower surface of the second contact separating layer higher than a lower surface of the first contact separating layer, the second contact separating layer including a material different from the material of the upper interlayer insulating layer, the second contact separating layer being in contact with the first contact separating layer; and
a lower source/drain contact electrically connected to the second source/drain region by penetrating through the lower interlayer insulating layer and the second insulating pattern in a vertical direction.

14. The semiconductor device of claim 13, further comprising:
an upper source/drain contact electrically connected to the first source/drain region by penetrating through the upper interlayer insulating layer in the vertical direction,
wherein the upper source/drain contact is in contact with a sidewall of the first contact separating layer in the first horizontal direction.

15. The semiconductor device of claim 13, wherein each of an upper surface of the upper interlayer insulating layer, an upper surface of the first contact separating layer, and an upper surface of the second contact separating layer are on the same plane.

16. The semiconductor device of claim 13, wherein the lower source/drain contact overlaps the second contact separating layer in the vertical direction.

17. The semiconductor device of claim 13, wherein the lower surface of the first contact separating layer is spaced apart from the etching stop layer, which is disposed on the upper surface of the field insulating layer, in the vertical direction.

18. The semiconductor device of claim 13, wherein the lower surface of the second contact separating layer is spaced apart from the etching stop layer, which is disposed on the upper surface of the second source/drain region, in the vertical direction.

19. The semiconductor device of claim 13, wherein the material of the second contact separating layer is different from the material of the first contact separating layer.

20. A semiconductor device comprising:
a lower interlayer insulating layer;
a first insulating pattern extended in a first horizontal direction on an upper surface of the lower interlayer insulating layer;
a second insulating pattern extended in the first horizontal direction on the upper surface of the lower interlayer insulating layer, the second insulating pattern being spaced apart from the first insulating pattern in a second horizontal direction different from the first horizontal direction;
a first plurality of nanosheets stacked to be spaced apart from each other in a vertical direction on the first insulating pattern;
a second plurality of nanosheets stacked to be spaced apart from each other in the vertical direction on the second insulating pattern;
a field insulating layer surrounding sidewalls of the first and second insulating patterns on the upper surface of the lower interlayer insulating layer;
a first gate electrode extended in the second horizontal direction on the first and second insulating patterns, the first gate electrode surrounding each of the first and second plurality of nanosheets;
a second gate electrode extended in the second horizontal direction on the first and second insulating patterns, the second gate electrode being spaced apart from the first gate electrode in the first horizontal direction;
a first source/drain region disposed between the first gate electrode and the second gate electrode on the first insulating pattern;
a second source/drain region disposed between the first gate electrode and the second gate electrode on the second insulating pattern;
an upper interlayer insulating layer covering the first and second source/drain regions on an upper surface of the field insulating layer;
an etching stop layer disposed between the upper surface of the field insulating layer and the upper interlayer insulating layer, the etching stop layer being in contact with a sidewall and an upper surface of the second source/drain region in the second horizontal direction;
a first contact separating layer disposed inside the upper interlayer insulating layer between the first and second source/drain regions, the first contact separating layer including a material different from a material of the upper interlayer insulating layer;
a second contact separating layer disposed inside the upper interlayer insulating layer on the upper surface of the second source/drain region, a lower surface of the second contact separating layer being at a level higher than a level of a lower surface of the first contact separating layer, the second contact separating layer including the same material as the material of the first contact separating layer, the second contact separating layer being in contact with the first contact separating layer;
an upper source/drain contact electrically connected to the first source/drain region by penetrating through the upper interlayer insulating layer in the vertical direction, the upper source/drain contact being in contact with a sidewall of the first contact separating layer in the first horizontal direction; and
a lower source/drain contact electrically connected to the second source/drain region by penetrating through the lower interlayer insulating layer and the second insulating pattern in the vertical direction,
wherein a lower surface of the upper source/drain contact is at a level higher than the level of the lower surface of the first contact separating layer,
wherein the lower surface of the upper source/drain contact is at a level lower than a level of the lower surface of the second contact separating layer,
wherein the lower surface of the first contact separating layer is in contact with the etching stop layer disposed on the upper surface of the field insulating layer, and
wherein the lower surface of the second contact separating layer is in contact with the etching stop layer disposed on the upper surface of the second source/drain region.
